(19) United States
(12) Patent Application Publication
(10) Pub. No.: US 2025/0351363 A1
(43) Pub. Date: Nov. 13, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventors: Hui Woo PARK, Gyeonggi-do (KR); Young Ock HONG, Gyeonggi-do (KR)

(21) Appl. No.: 18/766,673

(22) Filed: Jul. 9, 2024

(30) Foreign Application Priority Data
May 7, 2024 (KR) 10-2024-0059930

(51) Int. Cl. H10B 43/40; H01L 23/522; H01L 23/528; H10B 41/10; H10B 41/27; H10B 41/40; H10B 43/10; H10B 43/27

(52) U.S. Cl. CPC H10B 43/40; H01L 23/5226; H01L 23/5283; H10B 41/10; H10B 41/27; H10B 41/40; H10B 43/10; H10B 43/27

(57) ABSTRACT

A semiconductor device may include a peripheral circuit, a first gate structure positioned on the peripheral circuit, a first stack positioned at a level corresponding to the first gate structure, a source bonding structure positioned on the first gate structure, a first contact bonding structure positioned on the first stack, first channel structures extending into the source bonding structure through the first gate structure, a first contact plug extending into the first contact bonding structure through the first stack, a second gate structure positioned on the source bonding structure, a second stack positioned on the first contact bonding structure, second channel structures extending into the source bonding structure through the second gate structure, and a second contact plug extending into the first contact bonding structure through the second stack.

### CROSS-REFERENCE TO RELATED APPLICATION

This application claims priority under 35 U.S.C. § 119 to Korean Patent Application No. 10-2024-0059930 filed on May 7, 2024, which is incorporated herein by reference in its entirety.

### BACKGROUND

### 1. Technical Field

Embodiments of the present disclosure relate to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvements in an integration degree of a semiconductor device in which a memory cell is formed as a single layer on a substrate reach a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a peripheral circuit, a first gate structure positioned over the peripheral circuit and including first insulating layers and first conductive layers alternately stacked, a first stack positioned at a level corresponding to the first gate structure and including the first insulating layers and first sacrificial layers alternately stacked, a source bonding structure positioned on the first gate structure, a first contact bonding structure positioned on the first stack, first channel structures extending partially into the source bonding structure through the first gate structure, a first contact plug extending into the first contact bonding structure through the first stack, a second gate structure positioned on the source bonding structure and including second insulating layers and second conductive layers alternately stacked, a second stack positioned on the first contact bonding structure and including the second insulating layers and second sacrificial layers alternately stacked, second channel structures extending into the source bonding structure through the second gate structure, and a second contact plug extending into the first contact bonding structure through the second stack.

According to an embodiment of the present disclosure, a method of manufacturing a semiconductor device may include forming a first stack on a first substrate, forming first channel structures extending into the first substrate through the first stack, forming a first contact plug extending through the first stack, removing the first substrate, forming a first dielectric bonding layer on the first stack, forming first openings exposing the first channel structures by partially removing the first dielectric bonding layer, forming a second opening exposing the first contact plug by partially removing the first dielectric bonding layer, forming first source bonding patterns in the first openings, and forming a first contact bonding pattern in the second opening.

### BRIEF DESCRIPTION OF THE DRAWINGS

FIGS. 1A and 1B are simplified diagrams illustrating a semiconductor device according to an embodiment of the present disclosure.

FIGS. 2A to 2C are simplified diagrams illustrating a semiconductor device according to an embodiment of the present disclosure.

FIGS. 3 to 7 are simplified diagrams illustrating a method of manufacturing a semiconductor device according to an embodiment of the present disclosure.

FIG. 8 is a simplified diagram illustrating a method of manufacturing a semiconductor device according to an embodiment of the present disclosure.

FIG. 9 is a simplified diagram illustrating a method of manufacturing a semiconductor device according to an embodiment of the present disclosure.

FIG. 10 is a simplified diagram illustrating a memory system according to an embodiment of the present disclosure.

FIG. 11 is a simplified diagram illustrating a memory system according to an embodiment of the present disclosure.

FIG. 12 is a simplified diagram illustrating a memory system according to an embodiment of the present disclosure.

FIG. 13 is a simplified diagram illustrating a memory system according to an embodiment of the present disclosure.

FIG. 14 is a simplified diagram illustrating a memory system according to an embodiment of the present disclosure.

FIG. 15 is a simplified configuration diagram of a semiconductor device according to an embodiment of the present disclosure.

### DETAILED DESCRIPTION

According to embodiments of the present disclosure a semiconductor device and a method of manufacturing the semiconductor device are provided. The semiconductor device has a stable structure and exhibits improved characteristics and reliability.

Hereinafter, embodiments according to the technical concepts of the present disclosure are described with reference to the accompanying drawings.

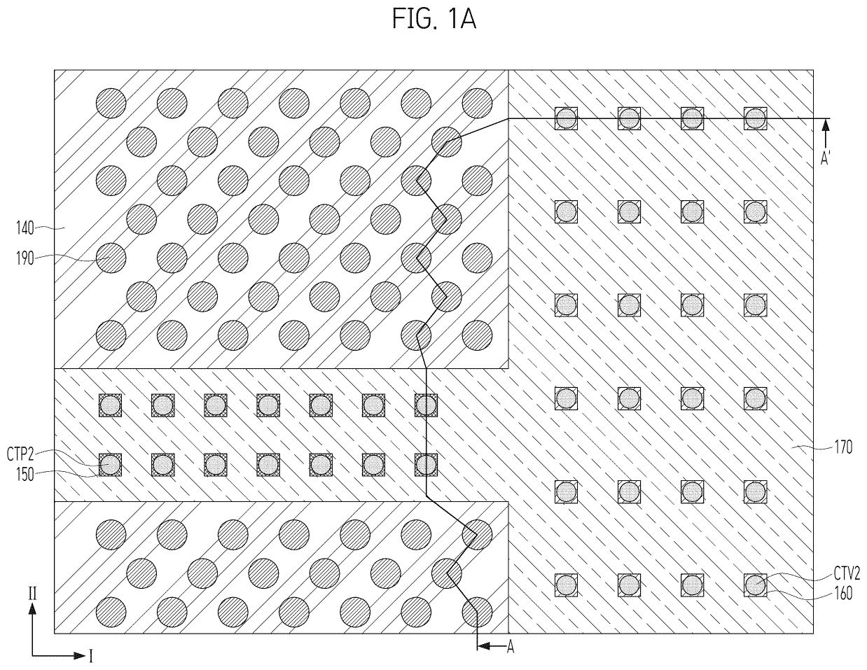

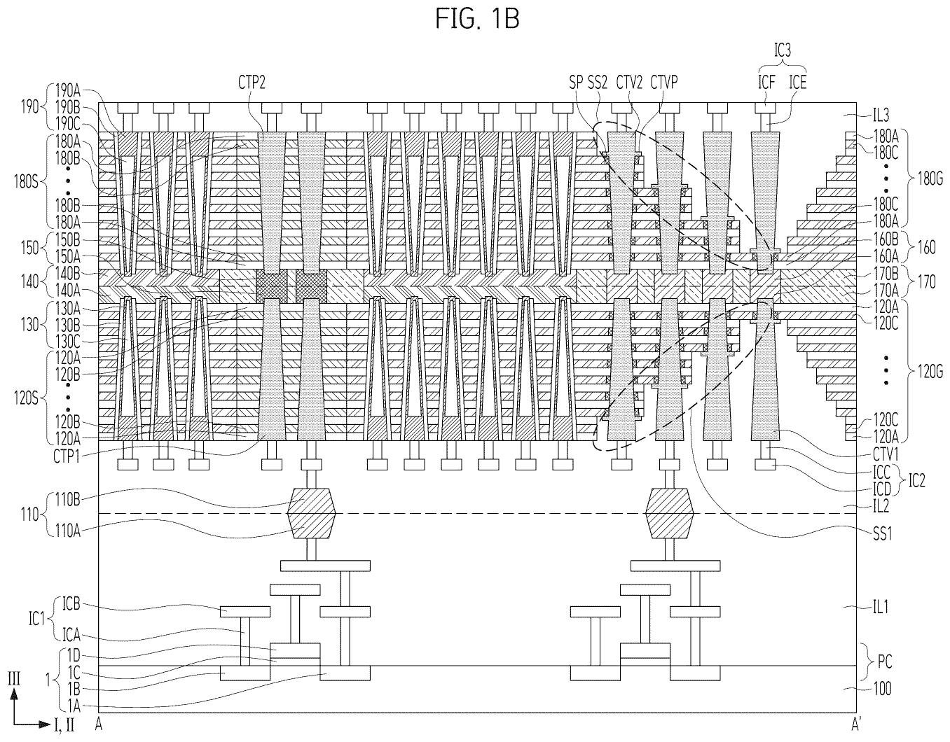

FIGS. 1A and 1B are simplified diagrams illustrating a semiconductor device according to an embodiment of the present disclosure. FIG. 1A is a plan view, and FIG. 1B is a cross-sectional view taken along line A-A′ of FIG. 1A.

Referring to FIGS. 1A and 1B, according to an embodiment, the semiconductor device may include a first stack 120S, a first gate structure 120G, a second stack 180S, a second gate structure 180G, a first channel structure 130, a second channel structure 190, a first contact plug CTP1, a second contact plug CTP2, a source bonding structure 140, a first contact bonding structure 150, a second contact bonding structure 160, and a dielectric bonding structure 170. The semiconductor device may further include a substrate 100, a peripheral circuit PC, a peripheral circuit bonding structure 110, a first interconnection structure IC1, a second interconnection structure IC2, a third interconnection structure IC3, a first interlayer insulating layer IL1, a second interlayer insulating layer IL2, a third interlayer insulating layer IL3, a first contact via CTV1, and a second contact via CTV2.

The peripheral circuit PC may be positioned on or over the substrate 100. The peripheral circuit PC may include at least one transistor 1 including junctions 1A and 1B, a gate electrode 1D, and a gate insulating layer 1C positioned between the gate electrode 1D and the substrate 100. An isolation layer ISO may be positioned in the substrate 100 and may define an active area. The at least one transistor 1 may be positioned in the active area.

The first interlayer insulating layer IL1 may be positioned on the substrate 100. The first interconnection structure IC1 may be positioned in the first interlayer insulating layer IL1. More specifically the first interconnection structure IC1 may be positioned on or over the substrate 100. The first interconnection structure IC1 may include at least one first via ICA extending in the stacking direction (i.e., perpendicularly to the top surface of the substrate, and at least one first line ICB extending in a direction parallel to the top surface of the substrate. The first interconnection structure IC1 may be connected to the peripheral circuit PC. For example, at least one of the first vias ICA may be connected to the transistor 1. The first vias ICA may connect the first lines ICB to each other. The first lines ICB may connect the first vias ICA to each other. The first interconnection structure IC1 may include a suitable conductive material such as, for example, tungsten. The first interlayer insulating layer IL1 may include a suitable insulating material such as, for example, an oxide or a nitride.

The peripheral circuit bonding structure 110 may be positioned on the first interconnection structure IC1. The peripheral circuit bonding structure 110 may include a first peripheral circuit bonding pad 110A and a second peripheral circuit bonding pad 110B. The first peripheral circuit bonding pad 110A may be positioned in the first interlayer insulating layer IL1. The second peripheral circuit bonding pad 110B may be positioned on the first peripheral circuit bonding pad 110A and may be positioned in the second interlayer insulating layer IL2. Here, the second interlayer insulating layer IL2 may be positioned on the first interlayer insulating layer IL1. The peripheral circuit bonding structure 110 may include a suitable conductive material such as, for example, copper, and the second interlayer insulating layer IL2 may include a suitable insulating material such as, for example, an oxide.

The second interconnection structure IC2 may be positioned on the peripheral circuit bonding structure 110. The second interconnection structure IC2 may be disposed inside the second interlayer insulating layer IL2 over the peripheral bonding structure 110. More specifically, the second interconnection structure IC2 may be positioned on the peripheral circuit bonding structure 110 and may contact the peripheral circuit bonding structure 110. The second interconnection structure IC2 may include at least one second via ICC and at least one second line ICD. Some of the second lines ICD may be used as bit lines. For example, among the second lines ICD, the second lines ICD connected to the first channel structures 130 may be used as bit lines. The second interconnection structure IC2 may be connected to the peripheral circuit bonding structure 110. For example, at least one of the second vias ICC may be connected to the second peripheral circuit bonding pad 110B. The second interconnection structure IC2 may include a suitable conductive material such as, for example, tungsten. The second interlayer insulating layer IL2 may include a suitable insulating material such as, for example, an oxide or a nitride.

The first gate structure 120G may be positioned over the peripheral circuit PC. For example, the first gate structure 120G may be positioned over the peripheral circuit bonding structure 110. The first gate structure 120G may include first insulating layers 120A and first conductive layers 120C alternately stacked. Here, the first conductive layers 120C may be a gate line. The gate line may include at least one of a word line, a source select line, and a drain select line. The first stack 120S may be positioned at a level corresponding to the first gate structure 120G and may include first insulating layers 120A and first sacrificial layers 120B alternately stacked. The first stack 120S may be a remaining structure that is not replaced with the first gate structure 120G. Here, the first insulating layers 120A may include an insulating material such as an oxide, the first sacrificial layers 120B may include a sacrificial material such as nitride, and the first conductive layers 120C may include a suitable conductive material such as, for example, tungsten, polysilicon, or molybdenum.

The first gate structure 120G may include a first step structure SS1. For example, the first gate structure 120G may include the first step structure SS1 exposing an upper surface of each of the first conductive layers 120C. Here, the first step structure SS1 may have an inverted step shape.

The source bonding structure 140 may be positioned on the first gate structure 120G. The source bonding structures 140 may be spaced apart from each other in a second direction II crossing a first direction I. The source bonding structure 140 may include a first source bonding pattern 140A and a second source bonding pattern 140B positioned on the first source bonding pattern 140A. In a process of manufacturing the semiconductor device, the first source bonding pattern 140A and the second source bonding pattern 140B may be bonded. The source bonding structure 140 may include a conductive material such as polysilicon.

The first contact bonding structure 150 may be positioned on the first stack 120S. The first contact bonding structure 150 may be positioned at a level corresponding to the source bonding structure 140. The first contact bonding structures 150 may be positioned between the source bonding structures 140 spaced apart in the second direction II. For example, the first contact bonding structures 150 may be positioned in the dielectric bonding structure 170. In this case, the first contact bonding structures 150 may be insulated from each other by the dielectric bonding structure 170.

The first contact bonding structures 150 may be arranged in the first direction I and the second direction II. The first contact bonding structure 150 may include a first contact bonding pattern 150A and a second contact bonding pattern 150B positioned on the first contact bonding pattern 150A. In the process of manufacturing the semiconductor device, the first contact bonding pattern 150A and the second contact bonding pattern 150B may be bonded. The first contact bonding structure 150 may include the same or substantially the same material as the source bonding structure 140. For example, the first contact bonding structure 150 may include a conductive material such as polysilicon.

The second contact bonding structure 160 may be positioned on the first gate structure 120G. The second contact bonding structure 160 may be positioned at a level corresponding to the source bonding structure 140. For example, the second contact bonding structure 160 may be positioned in the dielectric bonding structure 170. In this case, the second contact bonding structure 160 may be insulated from each other by the dielectric bonding structure 170.

The second contact bonding structures 160 may be arranged in the first direction I and the second direction II. The second contact bonding structure 160 may include a third contact bonding pattern 160A and a fourth contact bonding pattern 160B positioned on the third contact bonding pattern 160A. In the process of manufacturing the semiconductor device, the third contact bonding pattern 160A and the fourth contact bonding pattern 160B may be bonded to each other. The second contact bonding structure 160 may include the same or substantially the same material as the source bonding structure 140. For example, the second contact bonding structure 160 may include a conductive material such as polysilicon.

The dielectric bonding structure 170 may be positioned at a level corresponding to at least one of the source bonding structure 140, the first contact bonding structure 150, and the second contact bonding structure 160. For example, the dielectric bonding structure 170 may be positioned at a level corresponding to the source bonding structure 140 and the first contact bonding structure 150. The dielectric bonding structure 170 may be positioned between neighboring source bonding structures 140. The dielectric bonding structure 170 may include a first dielectric bonding pattern 170A and a second dielectric bonding pattern 170B positioned on the first dielectric bonding pattern 170A. In the process of manufacturing the semiconductor device, the first dielectric bonding pattern 170A and the second dielectric bonding pattern 170B may be bonded to each other. The dielectric bonding structure 170 may include a dielectric material.

According to an embodiment of the present disclosure, the semiconductor device may include the source bonding structure 140, the first contact bonding structure 150, the second contact bonding structure 160, and the dielectric bonding structure 170 as a bonding structure. In the process of manufacturing the semiconductor device, the source bonding structure 140, the first contact bonding structure 150, the second contact bonding structure 160, and the dielectric bonding structure 170 may be used as the bonding structure without forming separate bonding pads for bonding cell wafers to each other. The first source bonding pattern 140A and the second source bonding pattern 140B may be directly bonded, the first contact bonding pattern 150A and the second contact bonding pattern 150B may be directly bonded, the third contact bonding pattern 160A and the fourth contact bonding pattern 160B may be directly bonded, and the first dielectric bonding pattern 160A and the second dielectric bonding pattern 160B may be directly bonded.

In addition, the source bonding structure 140, the first contact bonding structure 150, and the second contact bonding structure 160 may include the same or substantially the same material. For example, the source bonding structure 140, the first contact bonding structure 150, and the second contact bonding structure 160 may include polysilicon. A manufacturing cost of the semiconductor device may be reduced by unifying the manufacturing of the source bonding structure 140, the first contact bonding structure 150, and the second contact bonding structure 160 in a single simultaneous operation.

The second gate structure 180G may be positioned on the source bonding structure 140. The second gate structure 180G may include second insulating layers 180A and second conductive layers 180C alternately stacked. Here, the second conductive layers 180C may be a gate line. The gate line may include at least one of a word line, a source select line, and a drain select line. The second stack 180S may be positioned on the first contact bonding structure 150 and may include second insulating layers 180A and second sacrificial layers 180B alternately stacked. The second stack 180S may be a remaining structure that is not replaced with the second gate structure 180G. Here, the second insulating layers 180A may include an insulating material such as an oxide, the second sacrificial layers 180B may include a sacrificial material such as nitride, and the second conductive layers 180C may include a suitable conductive material such as, for example, tungsten, polysilicon, or molybdenum.

The second gate structure 180G may include a second step structure SS2. For example, the second gate structure 180G may include the second step structure SS2 exposing an upper surface of each of the second conductive layers 180C. For example, the second step structure SS2 may have a shape that is symmetrical to the first step structure SS1 with a plane of symmetry extending parallel to the top surface of the substrate 100 and passing through the bonding interface of the second contact bonding structure 160. That is, the first and second step structures SS1, SS2 may be mirror images of each other.

The first channel structures 130 may extend partially into the source bonding structure 140 through the first gate structure 120G. Each of the first channel structures 130 may include at least one of a first channel layer 130A, a first memory layer 130B surrounding the first channel layer 130A, and a first insulating core 130C positioned in the first channel layer 130A.

The second channel structures 190 may extend partially into the source bonding structure 140 through the second gate structure 180G. Each of the second channel structures 190 may include at least one of a second channel layer 190A, a second memory layer 190B surrounding the second channel layer 190A, and a second insulating core 190C positioned in the second channel layer 190A.

The first channel structures 130 and the second channel structures 190 may share the source bonding structure 140. For example, the first channel structures 130 and the second channel structures 190 may share one source bonding structure 140.

The first contact plug CTP1 may extend partially into the first contact bonding structure 150 through the first stack 120S. The first contact plug CTP1 may extend through the first stack 120S and may be electrically connected to the peripheral circuit PC. The first contact plug CTP1 may include a suitable conductive material such as, for example, tungsten.

The second contact plug CTP2 may extend partially into the first contact bonding structure 150 through the second stack 180S. The second contact plug CTP2 may include a suitable conductive material such as, for example, tungsten.

The first and second contact plugs CTP1 and CTP2 may share the first contact bonding structure 150. For example, the first contact plug CTP1 and the second contact plug CTP2 may be electrically connected through the first contact bonding structure 150. One first contact plug CTP1 and one second contact plug CTP2 may share one first contact bonding structure 150. In this case, the second contact plug CTP2 may be electrically connected to the peripheral circuit PC through the first contact bonding structure 150 and the first contact plug CTP1.

The first contact vias CTV1 may extend through the first step structure SS1 of the first gate structure 120G and may be connected to the first conductive layers 120C. The first contact vias CTV1 may be connected to at least one of the first conductive layers 120C through a protrusion CTVP of the first contact vias CTV1. For example, the first contact vias CTV1 may be connected to the first conductive layers 120C of which the upper surface is exposed by the first step structure SS1, through the protrusion CTVP. The first contact vias CTV1 may extend through the first step structure SS1 and may be electrically connected to the peripheral circuit PC. An insulating spacer SP may be positioned between the first contact via CTV1 and the first conductive layers 120C. The first contact vias CTV1 may include a suitable conductive material such as, for example, tungsten. The insulating spacer SP may include an insulating material such as an oxide.

The second contact vias CTV2 may extend through the second step structure SS2 of the second gate structure 180G and may be connected to the second conductive layers 180C. The second contact vias CTV2 may be connected to at least one of the second conductive layers 180C through a protrusion CTVP of the second contact vias CTV2. For example, the second contact vias CTV2 may be connected to the second conductive layers 180C of which the upper surface is exposed by the second step structure SS2, through the protrusion CTVP. An insulating spacer SP may be positioned between the second contact via CTV2 and the second conductive layers 180C. The second contact vias CTV2 may include a suitable conductive material such as, for example, tungsten.

The first contact vias CTV1 and the second contact vias CTV2 may share the second contact bonding structure 160. For example, the first contact vias CTV1 and the second contact vias CTV2 may be electrically connected through the second contact bonding structure 160. One first contact via CTV1 and one second contact via CTV2 may share one second contact bonding structure 160. In this case, the second contact vias CTV2 may be electrically connected to the peripheral circuit PC through the second contact bonding structure 160 and the first contact vias CTV1.

The third interconnection structure IC3 may be positioned on the second gate structure 180G and/or the second stack 180S. The third interconnection structure IC3 may be disposed inside the third interlayer insulating layer IL3. Here, the third interlayer insulating layer IL3 may be positioned on the second gate structure 180G. The third interconnection structure IC3 may include at least one third via ICE and at least one third line ICF. The third interconnection structure IC3 may include a suitable conductive material such as, for example, tungsten. The third interlayer insulating layer IL3 may include a suitable insulating material such as, for example, an oxide or a nitride.

According to the structure described above, the source bonding structure 140 may be a source structure connected to the first channel structures 130 and the second channel structures 190 and may be used as a bonding structure. The first contact bonding structure 150 may be a contact structure electrically connecting the first contact plug CTP1 and the second contact plug CTP2 and may be used as a bonding structure. The second contact bonding structure 160 may be a contact structure electrically connecting the first contact via CTV1 and the second contact via CTV2 and may be used as a bonding structure.

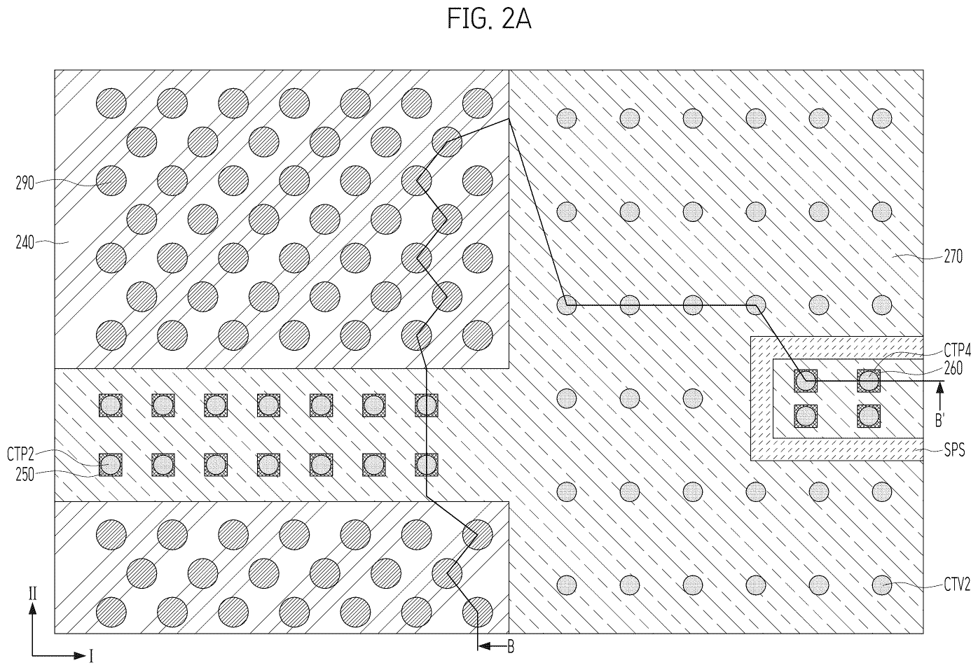

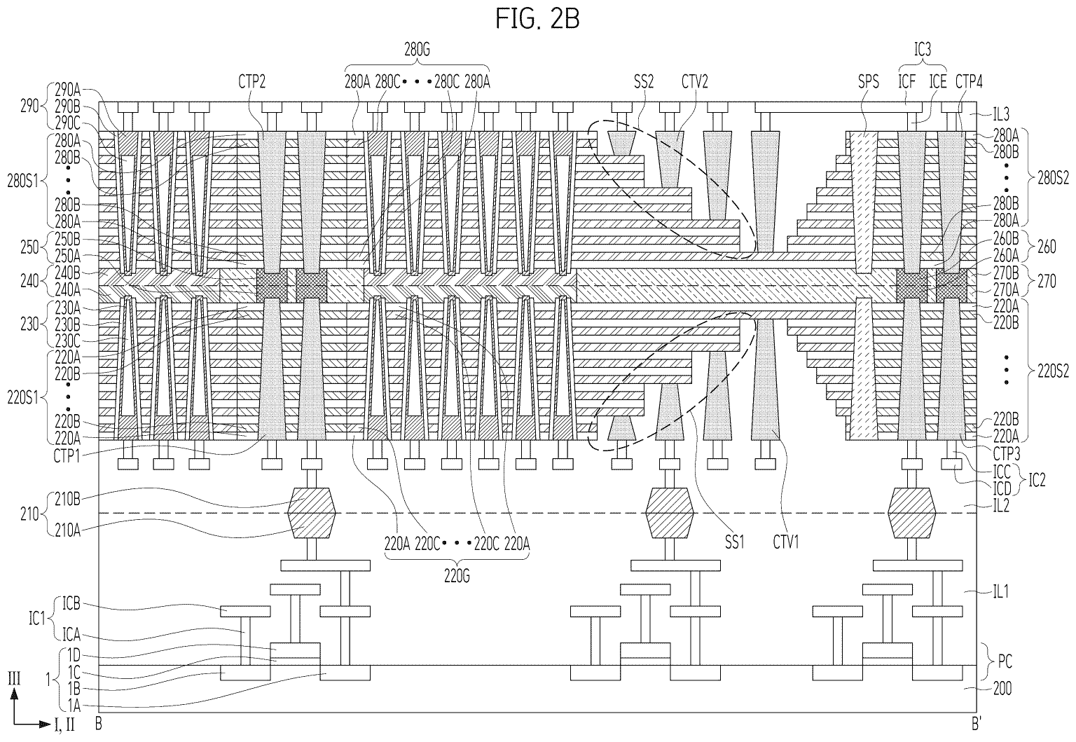

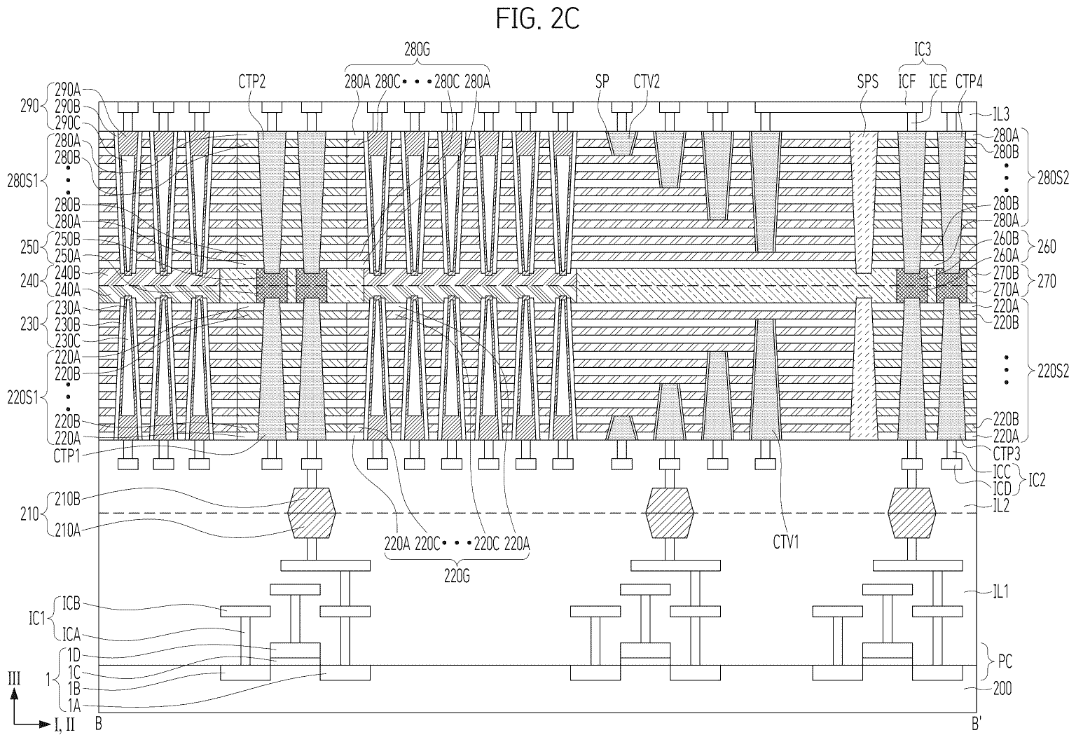

FIGS. 2A to 2C are simplified diagrams illustrating a semiconductor device according to an embodiment of the present disclosure. FIG. 2A is a plan view, and FIGS. 2B and 2C is a cross-sectional view taken along line B-B′ of FIG. 2A.

Referring to FIGS. 2A to 2C, the semiconductor device may include a first stack 220S1, a first gate structure 220G, a second stack 280S1, a second gate structure 280G, a third stack 220S2, a fourth stack 280S2, a first channel structure 230, a second channel structure 290, a first contact plug CTP1, a second contact plug CTP2, a source bonding structure 240, a first contact bonding structure 250, a third contact bonding structure 260, and a dielectric bonding structure 270. The semiconductor device may include at least one of a substrate 200, a peripheral circuit PC, a peripheral circuit bonding structure 210, a first interconnection structure IC1, a second interconnection structure IC2, a third interconnection structure IC3, a first interlayer insulating layer IL1, a second interlayer insulating layer IL2, a third interlayer insulating layer IL3, a first contact via CTV1, and a second contact via CTV2.

The peripheral circuit PC may be positioned on or over the substrate 200. The peripheral circuit PC may include a transistor 1. The transistor 1 may include junctions 1A and 1B, a gate electrode 1D, and a gate insulating layer 1C. An isolation layer ISO may be positioned in the substrate 200, and an active area may be defined by the isolation layer ISO. The transistor 1 may be positioned in the active area.

The first interconnection structure IC1 may be positioned on or over the substrate 200. The first interconnection structure IC1 may be positioned in the first interlayer insulating layer IL1. Here, the first interlayer insulating layer IL1 may be positioned on the substrate 200. The first interconnection structure IC1 may include at least one first via ICA and at least one first line ICB. The first interconnection structure IC1 may be connected to the peripheral circuit PC.

The peripheral circuit bonding structure 210 may be positioned on the first interconnection structure IC1. The peripheral circuit bonding structure 210 may include a first peripheral circuit bonding pad 210A and a second peripheral circuit bonding pad 210B. The first peripheral circuit bonding pad 210A may be positioned in the first interlayer insulating layer IL1. The second peripheral circuit bonding pad 210B may be positioned on the first peripheral circuit bonding pad 210A and may be positioned in the second interlayer insulating layer IL2. Here, the second interlayer insulating layer IL2 may be positioned on the first interlayer insulating layer IL1.

The second interconnection structure IC2 may be positioned on the peripheral circuit bonding structure 210. The second interconnection structure IC2 may be positioned in the second interlayer insulating layer IL2. The second interconnection structure IC2 may include at least one second via ICC and at least one second line ICD. Some of the second lines ICD may be used as a bit line. For example, among the second lines ICD, the second lines ICD connected to the first channel structures 230 may be used as the bit line. The second interconnection structure IC2 may be connected to the peripheral circuit bonding structure 210.

The first gate structure 220G may be positioned on or over the peripheral circuit bonding structure 210. The first gate structure 220G may include first insulating layers 220A and first conductive layers 220C alternately stacked. Here, the first conductive layers 220C may be a gate line. The gate line may include at least one of a word line, a source select line, and a drain select line. The first stack 220S1 may be positioned at a level corresponding to the first gate structure 220G and may include first insulating layers 220A and first sacrificial layers 220B alternately stacked. The third stack 220S2 may be positioned at a level corresponding to the first stack 220S1 and may include first insulating layers 220A and first sacrificial layers 220B alternately stacked. The first stack 220S1 and the third stack 220S2 may be a remaining structure that is not replaced with the first gate structure 220G.

Referring to FIG. 2B, the first gate structure 220G may include a first step structure SS1. For example, the first gate structure 220G may include the first step structure SS1 exposing an upper surface of each of the first conductive layers 220C. The first step structure SS1 may have an inverted step shape. Referring to FIG. 2C, the first gate structure 220G may not include the first step structure SS1.

The source bonding structure 240 may be positioned on the first gate structure 220G. The source bonding structures 240 may be spaced apart from each other in the second direction II crossing the first direction I. The source bonding structure 240 may include a first source bonding pattern 240A and a second source bonding pattern 240B positioned on the first source bonding pattern 240A. In a process of manufacturing the semiconductor device, the first source bonding pattern 240A and the second source bonding pattern 240B may be bonded. The source bonding structure 240 may include a conductive material such as polysilicon.

The first contact bonding structure 250 may be positioned on the first stack 220S1. The first contact bonding structure 250 may be positioned at a level corresponding to the source bonding structure 240. The first contact bonding structures 250 may be positioned between the source bonding structures 240 spaced apart in the second direction II. The first contact bonding structures 250 may be arranged in the first direction I and the second direction II. The first contact bonding structure 250 may include a first contact bonding pattern 250A and a second contact bonding pattern 250B positioned on the first contact bonding pattern 250A. In the process of manufacturing the semiconductor device, the first contact bonding pattern 250A and the second contact bonding pattern 250B may be bonded. The first contact bonding structure 250 may include the same or substantially the same material as the source bonding structure 240. For example, the first contact bonding structure 250 may include a conductive material such as polysilicon.

The third contact bonding structure 260 may be positioned on the third stack 220S2. The third contact bonding structure 260 may be positioned at a level corresponding to the source bonding structure 240. The third contact bonding structures 260 may be arranged in the first direction I and the second direction II. The third contact bonding structure 260 may include a fifth contact bonding pattern 260A and a sixth contact bonding pattern 260B positioned on the fifth contact bonding pattern 260A. In the process of manufacturing the semiconductor device, the fifth contact bonding pattern 260A and the sixth contact bonding pattern 260B may be bonded. The third contact bonding structure 260 may include the same or substantially the same material as the source bonding structure 240. For example, the third contact bonding structure 260 may include a conductive material such as polysilicon.

The dielectric bonding structure 270 may be positioned at a level corresponding to at least one of the source bonding structure 240, the first contact bonding structure 250, and the third contact bonding structure 260. The dielectric bonding structure 270 may include a first dielectric bonding pattern 270A and a second dielectric bonding pattern 270B positioned on the first dielectric bonding pattern 270A. In the process of manufacturing the semiconductor device, the first dielectric bonding pattern 270A and the second dielectric bonding pattern 270B may be bonded. The dielectric bonding structure 270 may include a dielectric material.

The second gate structure 280G may be positioned on the source bonding structure 240. The second gate structure 280G may include second insulating layers 280A and second conductive layers 280C alternately stacked. Here, the second conductive layers 280C may be a gate line. The gate line may include at least one of a word line, a source select line, and a drain select line. The second stack 280S1 may be positioned on the first contact bonding structure 250, and may include second insulating layers 280A and second sacrificial layers 280 alternately stacked. The fourth stack 280S2 may be positioned at a level corresponding to the second stack 280S1 and may include second insulating layers 280A and second sacrificial layers 280B alternately stacked. The second stack 280S1 and the fourth stack 280S2 may be a remaining structure that is not replaced with the second gate structure 280G.

Referring to FIG. 2B, the second gate structure 280G may include a second step structure SS2. For example, the second gate structure 280G may include the second step structure SS2 exposing an upper surface of each of the second conductive layers 280C. Here, the second step structure SS2 may have a shape symmetrical to the first step structure SS1. Referring to FIG. 2C, the second gate structure 280G may not include the second step structure SS2.

A support SPS may be positioned between the first gate structure 220G and the third stack 220S2 and between the second gate structure 280G and the fourth stack 280S2. The support SPS may distinguish an area where a third contact plug CTP3 and a fourth contact plug CTP4 are positioned and an area where the first contact vias CTV1 and the second contact vias CTV2 are positioned. One end of the first support SPS may contact the first gate structure 220G or the second gate structure 280G, and another end may contact the third stack 220S2 or the fourth stack 280S2. The support SPS may include an insulating material such as an oxide.

The first channel structures 230 may extend partially into the source bonding structure 240 through the first gate structure 220G. Each of the first channel structures 230 may include at least one of a first channel layer 230A, a first memory layer 230B surrounding the first channel layer 230A, and a first insulating core 230C positioned in the first channel layer 230A.

The second channel structures 290 may extend partially into the source bonding structure 240 through the second gate structure 280G. Each of the second channel structures 290 may include at least one of a second channel layer 290A, a second memory layer 290B surrounding the second channel layer 290A, and a second insulating core 290C positioned in the second channel layer 290A.

The first channel structures 230 and the second channel structures 290 may share the source bonding structure 240. For example, the first channel structures 230 and the second channel structures 290 may share one source bonding structure 240.

The first contact plug CTP1 may extend partially into the first contact bonding structure 250 through the first stack 220S1. The first contact plug CTP1 may extend through the first stack 220S1 and may be electrically connected to the peripheral circuit PC. The second contact plug CTP2 may extend partially into the first contact bonding structure 250 through the second stack 280S1.

The first contact plug CTP1 and the second contact plug CTP2 may share the first contact bonding structure 250. The second contact plug CTP2 may be electrically connected to the peripheral circuit PC through the first contact bonding structure 250 and the first contact plug CTP1.

The third contact plug CTP3 may extend into the third contact bonding structure 260 through the third stack 220S2. The third contact plug CTP3 may extend through the third stack 220S2 and may be electrically connected to the peripheral circuit PC.

The fourth contact plug CTP4 may be positioned on the third contact bonding structure 260 and may extend into the third contact bonding structure 260 through the fourth stack 280S2. The third contact plug CTP3 and the fourth contact plug CTP4 may share the third contact bonding structure 260. For example, the third contact plug CTP3 and the fourth contact plug CTP4 may be electrically connected through the third contact bonding structure 260. One third contact plug CTP3 and one fourth contact plug CTP4 may share one third contact bonding structure 260. In this case, the fourth contact plug CTP4 may be electrically connected to the peripheral circuit PC through the third contact bonding structure 260 and the first contact vias CTV1.

Referring to FIG. 2B, the first contact vias CTV1 may be directly connected to the upper surface of the first conductive layers 220C exposed through the first step structure SS1 of the first gate structure 220G. Here, the first contact vias CTV1 may have different heights. The second contact vias CTV2 may be directly connected to the upper surface of the second conductive layers 280C exposed through the second step structure SS2 of the second gate structure 280G. Here, the second contact vias CTV2 may have different heights.

Referring to FIG. 2C, the first contact vias CTV1 may extend through the first gate structure 220G and may be connected to the first conductive layers 220C. Here, the first contact vias CTV1 may have different heights. The second contact vias CTV2 may extend through the second gate structure 280G and may be connected to the second conductive layers 280C. Here, the second contact vias CTV2 may have different heights. An insulating spacer SP may be positioned on a sidewall of the first contact via CTV1 to insulate the remaining conductive layers 220C except for the first conductive layer 220C connected to the first contact via CTV1. Similarly, an insulating spacer SP may be positioned on a sidewall of the second contact via CTV2.

Comparing FIGS. 1B, 2B, and 2C, the first contact vias CTV1 and the second contact vias CTV2 of FIG. 1B may share the second contact bonding structure 160. Here, the second contact bonding structure 160 may be positioned between the first step structure SS1 and the second step structure SS2. The second contact vias CTV2 may be electrically connected to the second contact bonding structure 160 by passing through the second step structure SS2 of the second gate structure 180G. Therefore, the second contact vias CTV2 may be electrically connected to the peripheral circuit PC through the second contact bonding structure 160 and the first contact vias CTV1.

However, the first contact vias CTV1 and the second contact vias CTV2 of FIGS. 2B and 2C cannot share the second contact bonding structure 160 of FIG. 1B. In this case, the second contact bonding structure 160 may not exist between the first gate structure 220G and the second gate structure 280G, and the second contact vias CTV2 may not pass through the second gate structure 280G.

The third contact plug CTP3 and the fourth contact plug CTP4 may electrically connect the second contact vias CTV2 to the peripheral circuit PC. Here, the third contact bonding structure 260 may be positioned between the third stack 220S2 and the fourth stack 280S2. Therefore, the second contact vias CTV2 may be electrically connected to the peripheral circuit PC through the fourth contact plug CTP4, the third contact bonding structure 260, and the third contact plug CTP3.

The third interconnection structure IC3 may be positioned on the second gate structure 280G, the second stack 280S, and the fourth stack 280S2. The third interconnection structure IC3 may be positioned in the third interlayer insulating layer IL3. Here, the third interlayer insulating layer IL3 may be positioned on the second gate structure 280G. The third interconnection structure IC3 may include third vias ICE and third lines ICF.

According to the structure described above, heights of the first contact vias CTV1 may be different from each other, and heights of the second contact vias CTV2 may be different from each other. In this case, the first contact vias CTV1 may be directly connected to the peripheral circuit PC, and the second contact vias CTV2 may be electrically connected to the peripheral circuit PC through the fourth contact plug CTP4, the third contact bonding structure 260, and the third contact plug CTP3.

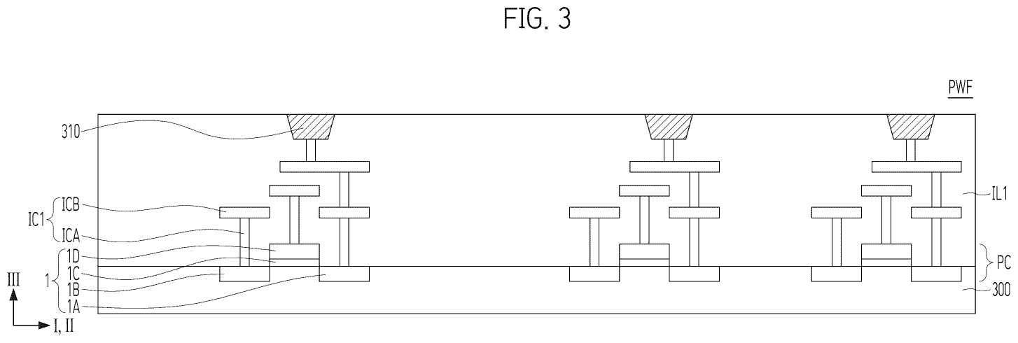

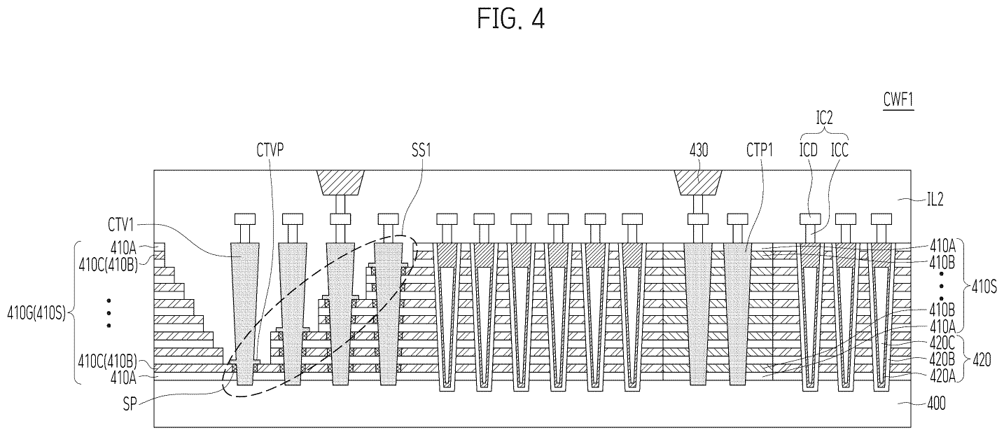

FIGS. 3 to 7 are simplified diagrams illustrating a method of manufacturing a semiconductor device according to an embodiment of the present disclosure. Hereinafter, content that overlaps the content described above is omitted.

Referring to FIG. 3, a peripheral circuit wafer PWF may be formed. A peripheral circuit PC may be formed on or over a first substrate 300. The peripheral circuit PC may include a transistor 1. The transistor 1 may include junctions 1A and 1B, a gate electrode 1D, and a gate insulating layer 1C. Here, the gate insulating layer 1C may be formed between the gate electrode 1D and the first substrate 300. An isolation layer ISO may be positioned in the first substrate 300, and an active area may be defined by the isolation layer ISO. The transistor 1 may be formed in the active area.

A first interconnection structure IC1 may be formed on or over the first substrate 300. Here, the first interconnection structure IC1 may be formed in a first interlayer insulating layer IL1. The first interlayer insulating layer IL1 may be formed on the first substrate 300. The first interconnection structure IC1 may include at least one first via ICA and at least one first line ICB. The first interconnection structure IC1 may be connected to the peripheral circuit PC. For example, at least one of the first vias ICA may be connected to the transistor 1. The first vias ICA may connect the first lines ICB to each other. The first lines ICB may connect the first vias ICA to each other. The first interconnection structure IC1 may include a suitable conductive material such as, for example, tungsten, copper, or aluminum. The first interlayer insulating layer IL1 may include a suitable insulating material such as, for example, an oxide or a nitride.

First peripheral circuit bonding pads 310 may be formed on the first interconnection structure IC1. The first peripheral circuit bonding pads 310 may include a suitable conductive material such as, for example, copper. Therefore, the peripheral circuit wafer PWF may be formed to include the first substrate 300, the peripheral circuit PC, the first interlayer insulating layer IL1, the first interconnection structure IC1, and the first peripheral circuit bonding pads 310.

Referring to FIG. 4, a first cell wafer CWF1 may be formed. A first stack 410S may be formed by alternately stacking first material layers 410A and second material layers 410B on or over a second substrate 400. The first stack 410S may include a first step structure SS1. An upper surface of each of the second material layers 410B of the first stack 410S may be exposed through the first step structure SS1. Here, the first material layers 410A may include an insulating material such as an oxide, and the second material layers 410B may include a sacrificial material such as a nitride. Alternatively, the second material layers 410B may include a conductive material such as molybdenum.

First channel structures 420 extending partially into the second substrate 400 through the first stack 410S may be formed. For example, the first channel structures 420 may include at least one of a first channel layer 420A, a first memory layer 420B surrounding the first channel layer 420A, and a first insulating core 420C in the first channel layer 420A.

A first contact plug CTP1 extending through the first stack 410S may be formed. For example, the first contact plug CTP1 extending partially into the second substrate 400 through the first stack 410S may be formed. The first contact plug CTP1 may include a suitable conductive material such as, for example, tungsten.

First contact vias CTV1 extending through the first stack 410S may be formed. The first contact vias CTV1 may be formed to extend through the first step structure SS1 and respectively connect to the second material layers 410B. The first contact vias CTV1 may include a protrusion and may contact the upper surface of the second material layer 410B exposed by the first step structure SS1, through the protrusion. To prevent contact between the first contact vias CTV1 and remaining second material layers 410B except for the second material layer 410B that contacts through the protrusion of the first contact vias CTV1, an insulating spacer SP may be formed on a sidewall of the first contact vias CTV1. The first contact vias CTV1 may include a suitable conductive material such as, for example, tungsten. The insulating spacer SP may include an insulating material such as an oxide. The insulating spacer SP may be formed between the first contact vias CTV1 and the second material layers 410B.

The second material layers 410B of the first stack 410S may be replaced with fifth material layers 410C. For example, the second material layers 410B may be replaced with the fifth material layers 410C through a first slit (not shown) extending through the first stack 410S. Accordingly, a first gate structure 410G in which the first material layers 410A and the fifth material layers 410C are alternately stacked may be defined. A partial area of the first stack 410S may not be replaced with the fifth material layers 410C. For example, in an area of the first stack 410S where the first contact plugs CTP1 are formed, the second material layers 410 may remain without being replaced with the fifth material layers 410C. Here, the fifth material layers 410C may include a suitable conductive material such as, for example, tungsten, molybdenum, or polysilicon.

For reference, when the second material layers 410B include a conductive material, a process of replacing the second material layers 410B with the fifth material layers 410C may be omitted. In this case, the first stack 410S may be used as the first gate structure 410G.

A second interconnection structure IC2 may be formed on the first stack 410S. Here, the second interconnection structure IC2 may be formed in the first interlayer insulating layer IL2. The second interlayer insulating layer IL2 may be formed on the first step structure SS1 of the first stack 410S. The second interconnection structure IC2 may include at least one second via ICC and at least one second line ICD. The second interconnection structure IC2 may be connected to at least one of the first channel structures 420, the first contact plugs CTP1, and the first contact vias CTV1. The second interconnection structure IC2 may include a suitable conductive material such as, for example, tungsten, copper, or aluminum. The second interlayer insulating layer IL2 may include a suitable insulating material such as, for example, an oxide or a nitride.

Second peripheral circuit bonding pads 430 may be formed on the second interconnection structure IC2. The second peripheral circuit bonding pads 430 may include a conductive material such as copper. Therefore, the first cell wafer CWF1 is formed to include the second substrate 400, the first stack 410S, the first gate structure 410G, the first channel structures 420, the first contact plugs CTP1, the first contact vias CTV1, the second interlayer insulating layer IL2, the second interconnection structure IC2, and the second peripheral circuit bonding pads 430.

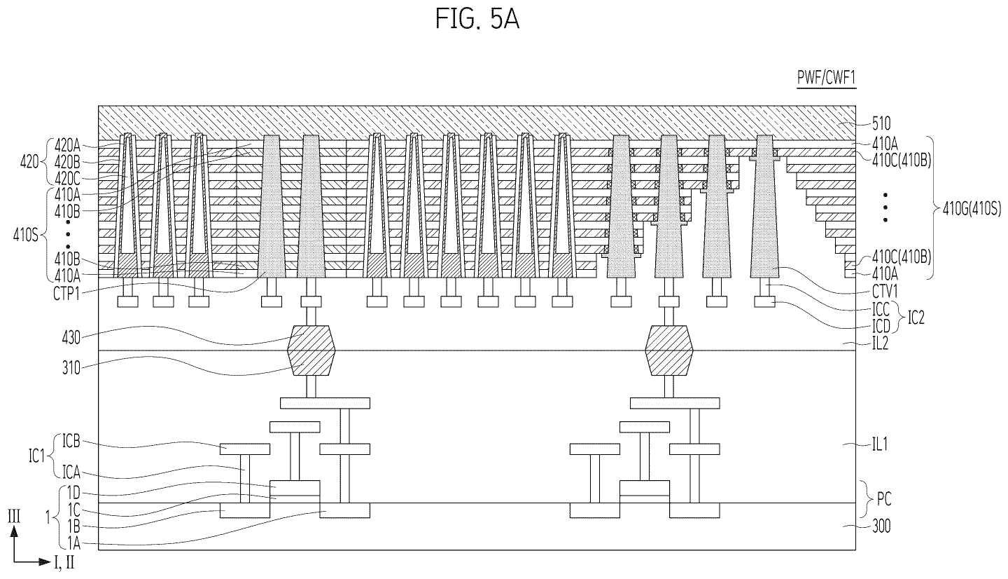

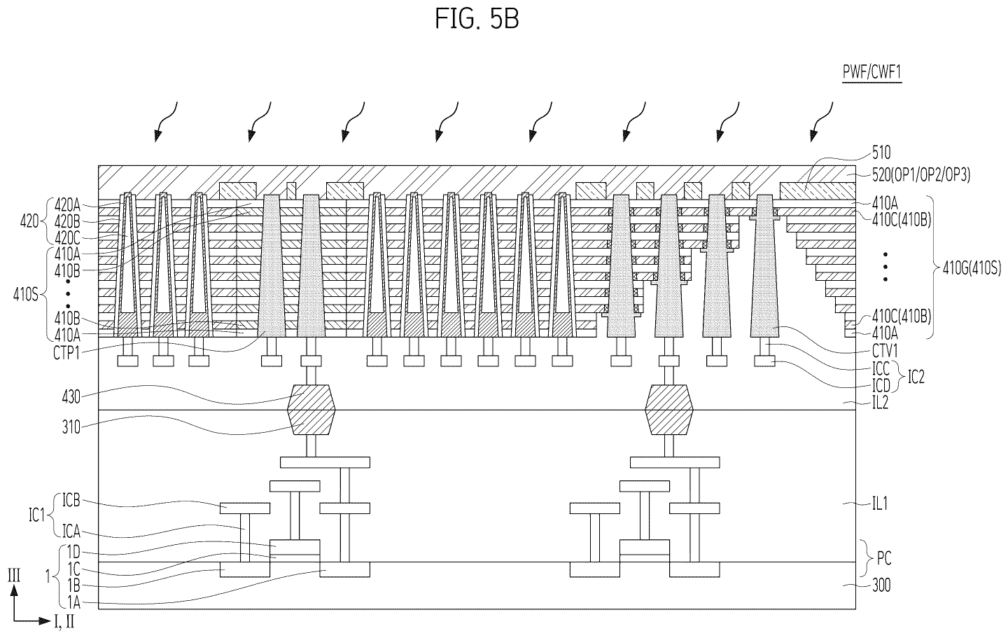

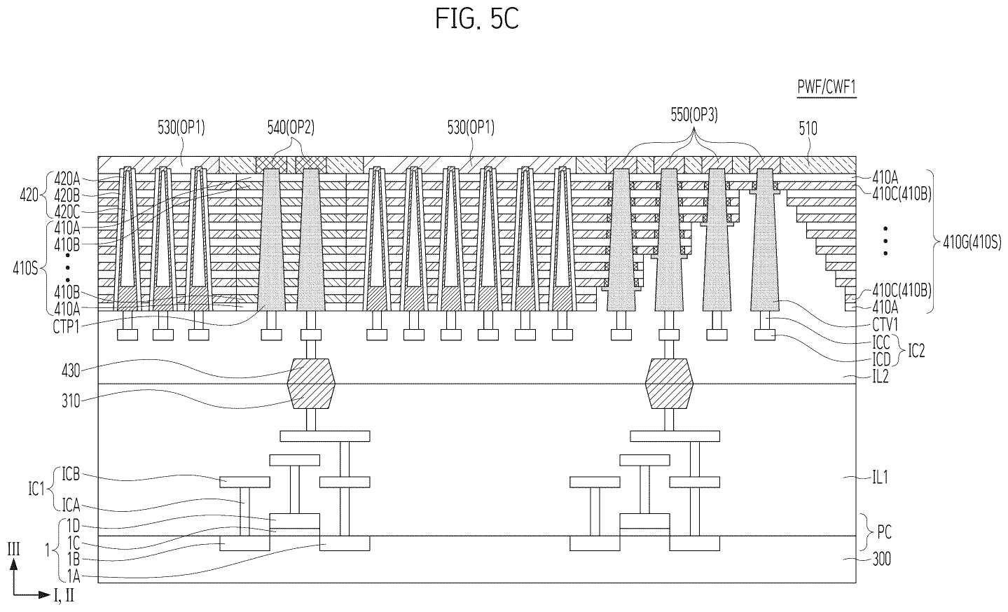

Referring to FIG. 5A, the peripheral circuit wafer PWF and the first cell wafer CWF1 may be bonded. For example, the first peripheral circuit bonding pads 310 of the peripheral circuit wafer PWF and the second peripheral circuit bonding pads 430 of the first cell wafer CWF1 may be directly bonded.

Subsequently, the second substrate 400 may be removed and the first channel structures 420, the first contact plugs CTP1, and the first contact vias CTV1 may be exposed by the removing of the second substrate 400. Subsequently, the first channel layer 420A may be exposed by partially removing the first memory layer 420B of the first channel structures 420.

Subsequently, a first dielectric bonding layer 510 may be formed on the first stack 410S in an area from where the second substrate 400 was removed. The first dielectric bonding layer 510 may include a dielectric material.

Referring to FIG. 5B, first openings OP1 exposing the first channel structures 420 may be formed by partially removing the first dielectric bonding layer 510. A second opening OP2 exposing the first contact plug CTP1 may be formed by partially removing the first dielectric bonding layer 510. Third openings OP3 exposing the first contact vias CTV1 may be formed by partially removing the first dielectric bonding layer 510. When forming the first openings OP1, the second opening OP2 may be formed. When forming the first openings OP1, the third openings OP3 may be formed.

Subsequently, a conductive bonding layer 520 may be formed to fill the first, second, and third openings OP1, OP2, and OP3. For example, the conductive bonding layer 520 may be formed on the first channel structures 420 to fill the first openings OP1. Here, the conductive bonding layer 520 may include a conductive material such as polysilicon. Subsequently, the conductive bonding layer 520 may be annealed.

Referring to FIG. 5C, first source bonding patterns 530 may be formed in the first openings OP1. For example, the first source bonding patterns 530 may be formed in the first openings OP1 by planarizing the conductive bonding layer 520 using the first dielectric bonding layer 510 as a planarization barrier. In this case, the first channel layer 420A of the first channel structures 420 may be connected to the first source bonding pattern 520.

A first contact bonding pattern 540 may be formed in the second openings OP2. When forming the first source bonding patterns 530, the first contact bonding patterns 540 may be formed. The first contact plugs CTP1 may be connected to corresponding first contact bonding patterns 540 in a one to one correspondence. Hence, one first contact plug CTP1 may be connected to one first contact bonding pattern 540. Neighboring first contact bonding patterns 540 may be insulated from each other by the first dielectric bonding layer 510.

Second contact bonding patterns 550 may be formed in the third openings OP3. When forming the first source bonding patterns 530, the second contact bonding patterns 550 may be formed. The first contact vias CTV1 may be connected to corresponding second contact bonding patterns 550 in a one to one correspondence. Hence, one first contact via CTV1 may be connected to one second contact bonding pattern 550. Neighboring second contact bonding patterns 550 may be insulated from each other by the first dielectric bonding layer 510.

According to an embodiment of the present disclosure, when forming the first source bonding patterns 530 by patterning the conductive bonding layer 520, the first contact bonding patterns 540 and the second contact bonding patterns 550 may be formed simultaneously. In this case, a manufacturing cost of the semiconductor device may be reduced by unifying the process of forming the first source bonding patterns 530, the first contact bonding patterns 540, and the second contact bonding patterns 550.

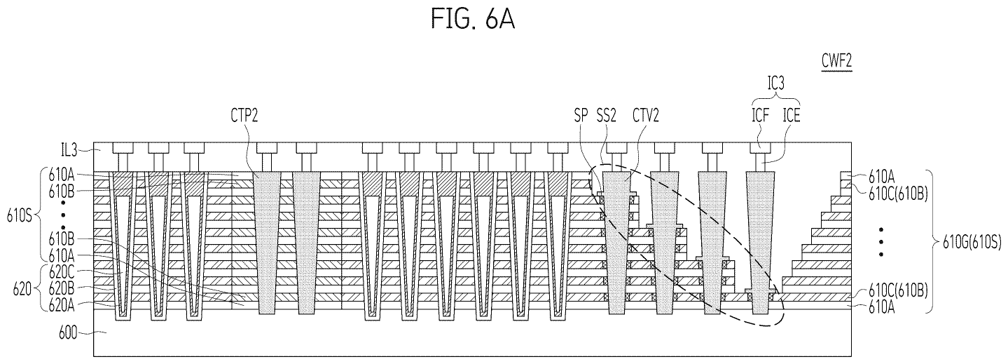

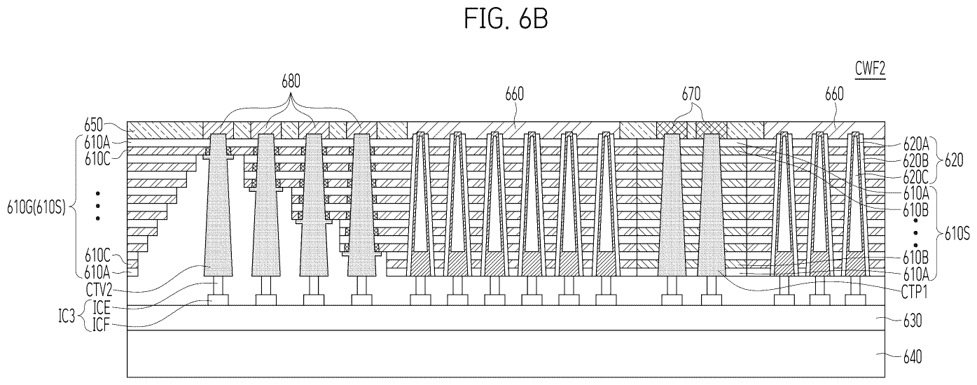

Referring to FIG. 6A, a second cell wafer CWF2 may be formed using, for example, the method of forming the first cell wafer CWF1 of FIG. 4. For example, the second cell wafer CWF2 may be formed to include a third substrate 600, a second stack 610S, a second gate structure 610G, second channel structures 620, second contact plugs CTP2, second contact vias CTV2, a third interlayer insulating layer IL3, and a third interconnection structure IC3.

Here, the second stack 610S may include third material layers 610A and fourth material layers 610B alternately stacked. The second stack 610S may include a second step structure SS2. An upper surface of each of the fourth material layers 610B may be exposed through the second step structure SS2. The second stack 610S may be replaced with a second gate structure 610G, and the second gate structure 610G may include third material layers 610A and sixth material layers 610C alternately stacked.

The second channel structures 620 may extend through the second gate structure 610G, and each of the second channel structures 620 may include a second channel layer 620A, a second memory layer 620B, and a second insulating core 620C. The second contact plugs CTP2 may extend through the second stack 610S. The second contact vias CTV2 may extend through the second gate structure 610G. For example, the second contact vias CTV2 may extend through the second step structure SS2 of the second gate structure 610G, and may be connected to the sixth material layers 610C, respectively.

Referring to FIG. 6B, the second cell wafer CWF2 may be rotated. First, a dummy bonding layer 630 may be formed on the second cell wafer CWF2. Subsequently, the dummy bonding layer 630 and a dummy substrate 640 may be bonded. In this case, the second cell wafer CWF2 may be rotated so that a lower surface of the third substrate 600 is exposed.

Subsequently, a second dielectric bonding layer 650, second source bonding patterns 660, third contact bonding patterns 670, and fourth contact bonding patterns 680 of the second cell wafer CWF2 may be formed using the method of forming the first dielectric bonding layer 510, the first source bonding patterns 530, the first contact bonding patterns 540, and the second contact bonding patterns 550 of the first cell wafer CWF1 of FIGS. 5A to 5C.

The second dielectric bonding layer 650 may be formed on the second stack 610S. The second source bonding patterns 660 may be formed on the second gate structure 610G. The third contact bonding patterns 670 and the fourth contact bonding patterns 680 may be formed at a level corresponding to the second source bonding patterns 660. The second channel layer 620A of the second channel structures 620 may be connected to the second source bonding pattern 660. The second contact plug CTP2 may be connected to the third contact bonding pattern 670. Here, one second contact plug CTP2 may be connected to one third contact bonding pattern 670. Neighboring third contact bonding patterns 670 may be insulated from each other by the second dielectric bonding layer 650. The second contact vias CTV2 may be connected to the fourth contact bonding patterns 680. Here, one second contact via CTV2 may be connected to one fourth contact bonding pattern 680. Neighboring fourth contact bonding patterns 680 may be insulated from each other by the second dielectric bonding layer 650.

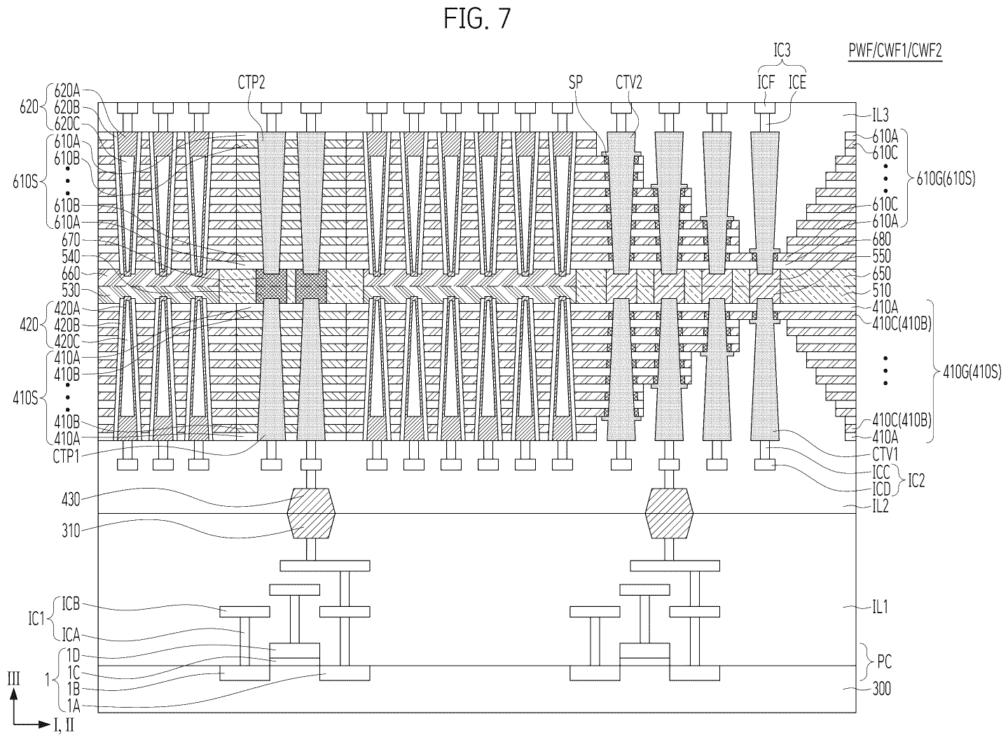

Referring to FIG. 7, the first cell wafer CWF1 and the second cell wafer CWF2 may be bonded. For example, the first cell wafer CWF1 and the second cell wafer CWF2 may be bonded so that the first source bonding patterns 530 and the second source bonding patterns 660 may be connected, the first contact bonding pattern 540 and the third contact bonding pattern 670 may be connected, the second contact bonding pattern 550 and the fourth contact bonding pattern 680 may be connected, and the first dielectric bonding layer 510 and the second dielectric bonding layer 650 may be connected.

According to an embodiment of the present disclosure, separate bonding pads may not be formed to bond the first cell wafer CWF1 and the second cell wafer CWF2. For example, the conductive bonding layer 520 may be formed on the first dielectric bonding layer 510 of the first cell wafer CWF1. The first source bonding patterns 530, the first contact bonding patterns 540, and the second contact bonding patterns 550 may be formed by patterning the conductive bonding layer 520 using the first dielectric bonding layer 510 as a planarization barrier. Similarly, the second dielectric bonding layer 650, the second source bonding patterns 660, the third contact bonding patterns 670, and the fourth contact bonding patterns 680 of the second cell wafer CWF2 may be formed.

In this case, the first channel structures 420 and the second channel structures 620 may share the second source bonding patterns 660 and the first source bonding patterns 530. The second contact plug CTP2 may be electrically connected to the third contact bonding pattern 670, the first contact bonding pattern 540, and the first contact plug CTP1, and may be electrically connected to the peripheral circuit PC. The second contact vias CTV2 may be electrically connected to the fourth contact bonding pattern 680, the second contact bonding pattern 550, and the second contact vias CTP2, and may be electrically connected to the peripheral circuit PC.

According to the manufacturing method described above, the second channel structures 620 of the second cell wafer CWF2 may share the first channel structures 420, the second source bonding patterns 660, and the first source bonding patterns 530. The second contact plug CTP2 of the second cell wafer CWF2 may be electrically connected to the peripheral circuit PC through the first contact plug CTP1, and the second contact vias of the second cell wafer CWF2 CTV2 may be electrically connected to the peripheral circuit PC through the first contact vias CTV1.

In addition, a manufacturing cost of the semiconductor device may be advantageously reduced by unifying a process of forming the source bonding patterns 530 and 660, the contact bonding patterns 540 and 670, and the contact bonding patterns 550 and 680 of the cell wafers CWF1 and CWF2.

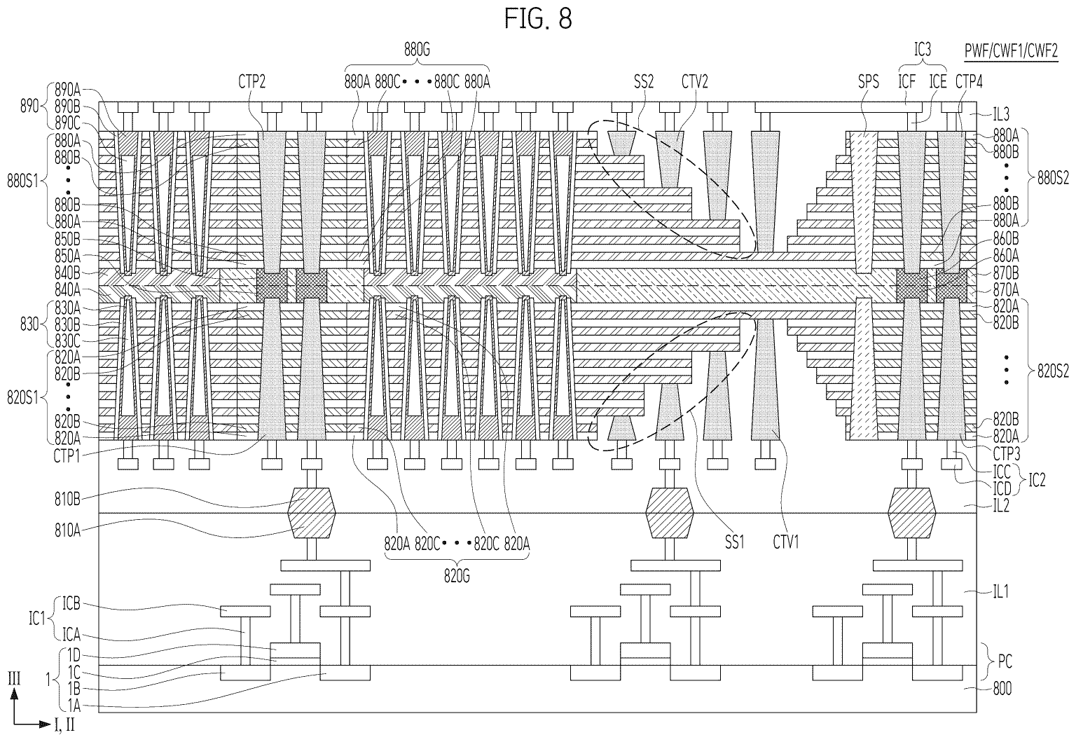

FIG. 8 is a simplified diagram illustrating a method of manufacturing a semiconductor device according to an embodiment of the present disclosure. Hereinafter, content that overlaps the content described above is omitted.

Referring to FIG. 8, a peripheral circuit wafer PWF may be formed. For example, the peripheral circuit wafer PWF may be formed using the method of forming the peripheral circuit wafer PWF of FIG. 3. Here, the peripheral circuit wafer PWF may include a first substrate 800, a peripheral circuit PC, a first interlayer insulating layer IL1, a first interconnection structure IC1, and a first peripheral circuit bonding pad 810A.

A first cell wafer CWF1 may be formed, for example, using the method of forming the first cell wafer CWF1 of FIGS. 4 to 5C. Here, the first cell wafer CWF1 may include a second peripheral circuit bonding pad 810B, a second interlayer insulating layer IL2, a second interconnection structure IC2, a first stack 820S1, a third stack 820S2, a first gate structure 820G, first channel structures 830, first source bonding patterns 840A, first contact bonding patterns 850A, fifth contact bonding patterns 860A, a first dielectric bonding layer 870A, first contact plugs CTP1, third contact plugs CTP3, and first contact vias CTV1.

Here, the first stack 820S1 may include first material layers 820A and second material layers 820B alternately stacked. The first stack 820S1 may include a first step structure SS1 exposing an upper surface of each of the second material layers 820B. The first stack 820S1 may be replaced with the first gate structure 820G. The first contact vias CTV1 may be directly connected to an upper surface of each of fifth material layers 820C exposed through the first step structure SS1 of the first gate structure 820G. The first contact vias CTV1 may have different heights. The first contact vias CTV1 may be electrically connected to the peripheral circuit PC.

The fifth contact bonding pattern 860A may be formed at a level corresponding to the first source bonding pattern 840A. The third contact plugs CTP3 may extend into the fifth contact bonding pattern 860A through the third stack 820S2. Here, the third stack 820S2 may be formed at a level corresponding to the first stack 820S1. The third contact plugs CTP3 may be electrically connected to the peripheral circuit PC.

A second cell wafer CWF2 may be formed. For example, the second cell wafer CWF2 may be formed using the method of forming the second cell wafer CWF2 of FIGS. 6A and 6B. Here, the second cell wafer CWF2 may include second source bonding patterns 840B, second contact bonding patterns 850B, sixth contact bonding patterns 860B, a second dielectric bonding layer 870B, a second dielectric bonding layer 870B, a second stack 880S1, a fourth stack 880S2, a second gate structure 880G, second channel structures 890, second contact plugs CTP2, fourth contact plugs CTP4, second contact vias CTV2, a support SPS, a third interconnection structure IC3, and a third interlayer insulating layer IL3.

Here, the second stack 880S1 may include third material layers 880A and fourth material layers 880B alternately stacked. The second stack 880S1 may include a second step structure SS2 exposing an upper surface of each of the fourth material layers 880B. The second stack 880S1 may be replaced with the second gate structure 880G. The second contact vias CTV2 may be directly connected to the upper surface of each of the sixth material layers 880C exposed through the second step structure SS2 of the second gate structure 880G. The second contact vias CTV2 may have different heights.

The sixth contact bonding pattern 860B may be formed at a level corresponding to the second source bonding pattern 840B. The fourth contact plugs CTP4 may extend into the sixth contact bonding pattern 860B through the fourth stack 880S2. Here, the fourth stack 880S2 may be formed at a level corresponding to the second stack 880S1. The fourth contact plugs CTP4 may be electrically connected to the peripheral circuit PC through the third contact plug CTP3.

The first source bonding pattern 840A may be bonded to the second source bonding pattern 840B, the first contact bonding pattern 850A may be bonded to the second contact bonding pattern 850B, and the fifth contact bonding pattern 860A may be bonded to the sixth contact bonding pattern 860B.

The second contact vias CTV2 may be connected to the fourth contact plug CTP4 through the third interconnection structure IC3. Therefore, the second contact vias CTV2 may be electrically connected to the fourth contact plug CTP4, the sixth contact bonding pattern 860B, and the fifth contact bonding pattern 860A, and may be connected to the peripheral circuit PC.

According to the manufacturing method described above, the fifth contact bonding pattern 860A and the sixth contact bonding pattern 860B may be formed between the third stack 820S2 and the fourth stack 880S2. The third contact plug CTP3 may extend into the fifth contact bonding pattern 860A, and the fourth contact plug CTP4 may extend into the sixth contact bonding pattern 860B. Here, the fifth contact bonding pattern 860A and the sixth contact bonding pattern 860B may be bonded, and the third contact plug CTP3 and fourth contact plug CTP4 may be electrically connected.

In addition, the first contact vias CTV1 directly connected to the upper surface of the fifth conductive layers 820C of which the upper surface is exposed by the first step structure SS1 of the first gate structure 820G may be formed, and the second contact vias CTV2 directly connected to the upper surface of the sixth conductive layers 880C of which the upper surface is exposed by the second step structure SS2 of the second gate structure 880G may be formed. In this case, the first contact vias CTV1 may be directly connected to the peripheral circuit PC, and the second contact vias CTV2 may be electrically connected to the peripheral circuit PC through the fourth contact plug CTP4, the sixth contact bonding pattern 860B, and the fifth contact bonding pattern 860A.

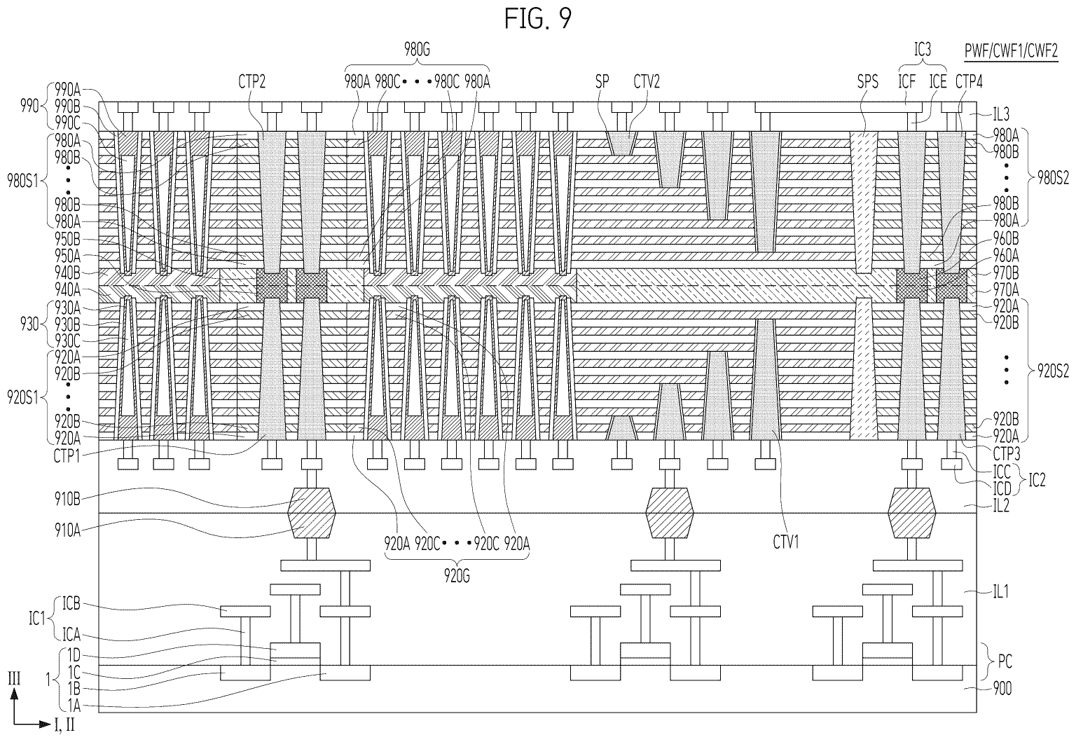

FIG. 9 is a simplified diagram illustrating a method of manufacturing a semiconductor device according to an embodiment of the present disclosure. Hereinafter, content that overlaps the content described above is omitted.

A peripheral circuit wafer PWF may be formed. For example, the peripheral circuit wafer PWF may be formed using the method of forming the peripheral circuit wafer PWF of FIG. 3. Here, the peripheral circuit wafer PWF may include a first substrate 900, a peripheral circuit PC, a first interlayer insulating layer IL1, a first interconnection structure IC1, and a first peripheral circuit bonding pad 910A.

A first cell wafer CWF1 may be formed. For example, the first cell wafer CWF1 may be formed using the method of forming the first cell wafer CWF1 of FIGS. 4 to 5C. Here, the first cell wafer CWF1 may include a second peripheral circuit bonding pad 910B, a second interlayer insulating layer IL2, a second interconnection structure IC2, a first stack 920S1, a third stack 920S2, a first gate structure 920G, first channel structures 930, first source bonding patterns 940A, first contact bonding patterns 950A, fifth contact bonding patterns 960A, a first dielectric bonding layer 970A, first contact plugs CTP1, third contact plugs CTP3, and first contact vias CTV1.

Here, the first stack 920S1 may include first material layers 920A and second material layers 920B alternately stacked. In comparison to FIG. 8, the first stack 920S1 may not include the first step structure. The first contact vias CTV1 may extend through the first stack 920S1 and may be connected to the second material layers 920B. The first contact vias CTV1 may have different heights. The first contact vias CTV1 may be electrically connected to the peripheral circuit PC.

The fifth contact bonding pattern 960A may be formed at a level corresponding to the first source bonding pattern 940A. The third contact plugs CTP3 may extend into the fifth contact bonding pattern 960A through the third stack 920S2. Here, the third stack 920S2 may be formed at a level corresponding to the first stack 920S1. The third contact plugs CTP3 may be electrically connected to the peripheral circuit PC.

A second cell wafer CWF2 may be formed, for example, by using the method of forming the second cell wafer CWF2 of FIGS. 6A and 6B. Here, the second cell wafer CWF2 may include second source bonding patterns 940B, second contact bonding patterns 950B, sixth contact bonding patterns 960B, a second dielectric bonding layer 970B, a second dielectric bonding layer 970B, a second stack 980S1, a fourth stack 980S2, a second gate structure 980G, second channel structures 990, second contact plugs CTP2, fourth contact plugs CTP4, second contact vias CTV2, a support SPS, a third interconnection structure IC3, and a third interlayer insulating layer IL3.

Here, the second stack 980S1 may include third material layers 980A and fourth material layers 980B alternately stacked. In comparison to FIG. 8, the second stack 980S1 may not include the second step structure. The second contact vias CTV2 may extend through the second stack 980S1 and may be connected to the fourth material layers 980B. The second contact vias CTV2 may have different heights.

The sixth contact bonding pattern 960B may be formed at a level corresponding to the second source bonding pattern 940B. The fourth contact plugs CTP4 may extend into the sixth contact bonding pattern 960B through the fourth stack 980S2. The fourth stack 980S2 may be formed at a level corresponding to the second stack 980S1. The fourth contact plugs CTP4 may be electrically connected to the peripheral circuit PC through the third contact plugs CTP3.

The first source bonding pattern 940A may be bonded to the second source bonding pattern 940B, the first contact bonding pattern 950A may be bonded to the second contact bonding pattern 950B, and the fifth contact bonding pattern 960A may be bonded to the sixth contact bonding pattern 960B.

The second contact vias CTV2 may be connected to the fourth contact plug CTP4 through the third interconnection structure IC3. Therefore, the second contact vias CTV2 may be electrically connected to the fourth contact plugs CTP4, the sixth contact bonding patterns 960B, and the fifth contact bonding patterns 960A, and may be connected to the peripheral circuit PC.

According to the manufacturing method described above, the fifth contact bonding patterns 960A and the sixth contact bonding patterns 960B may be formed between the third and fourth stacks 920S2 and 980S2. The third contact plug CTP3 may extend into the fifth contact bonding pattern 960A, and the fourth contact plug CTP4 may extend into the sixth contact bonding pattern 960B. Here, the fifth contact bonding pattern 960A and the sixth contact bonding pattern 960B may be bonded to each other, and the third contact plug CTP3 and fourth contact plug CTP4 may be electrically connected.

In addition, the first contact vias CTV1 directly connected to the fifth conductive layers 920C by extending through the first gate structure 920G may be formed, and the second contact vias CTV2 directly connected to the sixth conductive layers 980C by extending through the second gate structure 980G may be formed. In this case, the first contact vias CTV1 may be directly connected to the peripheral circuit PC, and the second contact vias CTV2 may be electrically connected to the peripheral circuit PC through the fourth contact plug CTP4, the sixth contact bonding pattern 960B, and the fifth contact bonding pattern 960A.

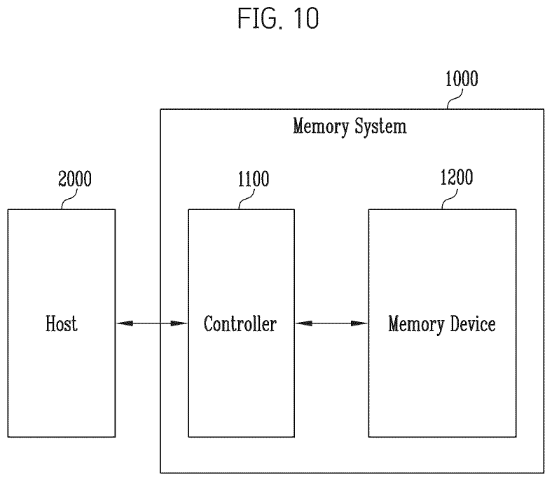

FIG. 10 is a simplified diagram illustrating a memory system according to an embodiment of the present disclosure.

Referring to FIG. 10, the memory system 1000 may include a memory device 1200 in which data is stored, and a controller 1100 communicating between the memory device 1200 and a host 2000.

The host 2000 may be a device or a system that stores data in the memory system 1000 or retrieves data from the memory system 1000. The host 2000 may generate requests for various operations and may output the generated requests to the memory system 1000. The requests may include a program request for a program operation, a read request for a read operation, an erase request for an erase operation, and the like. The host 2000 may communicate with the memory system 1000 through various communication standards or interfaces such as peripheral component interconnect express (PCIe), advanced technology attachment (ATA), serial ATA (SATA), parallel ATA (PATA), serial attached SCSI (SAS), non-volatile memory express (NVMe), universal serial bus (USB), multi-media card (MMC), enhanced small disk interface (ESDI), or integrated drive electronics (IDE).

The host 2000 may include at least one of a computer, a portable digital device, a tablet, a digital camera, a digital audio player, a television, a wireless communication device, or a cellular phone, but embodiments of the present disclosure are not limited thereto.

The controller 1100 may generally control an operation of the memory system 1000. The controller 1100 may control the memory device 1200 according to the request of the host 2000. The controller 1100 may control the memory device 1200 so that the program operation, the read operation, the erase operation, and the like may be performed according to the request of the host 2000. Alternatively, the controller 1100 may perform a background operation or the like for improving performance of the memory system 1000 even though the request of the host 2000 does not exist.

The controller 1100 may transmit a control signal and a data signal to the memory device 1200 in order to control the operation of the memory device 1200. The control signal and the data signal may be transmitted to the memory device 1200 through different input/output lines. The data signal may include a command, an address, or data. The control signal may be used to divide a section in which the data signal is input.

The memory device 1200 may perform the program operation, the read operation, the erase operation, and the like under control of the controller 1100. The memory device 1200 may be implemented as a volatile memory device in which stored data is destroyed when power supply is cut off, or a non-volatile memory device in which stored data is maintained even though power supply is cut off.

The memory device 1200 may be a semiconductor device having the structure previously described with reference to FIGS. 1A, 1B, and 2A to 2C. The memory device 1200 may be the semiconductor device manufactured using the manufacturing method previously described with reference to FIGS. 3 to 7, 8, and 9. In an embodiment, a semiconductor device may include a peripheral circuit; a first gate structure positioned over the peripheral circuit and including first insulating layers and first conductive layers alternately stacked; a first stack positioned at a level corresponding to the first gate structure and including the first insulating layers and first sacrificial layers alternately stacked; a source bonding structure positioned on the first gate structure; a first contact bonding structure positioned on the first stack; first channel structures extending into the source bonding structure through the first gate structure; a first contact plug extending into the first contact bonding structure through the first stack; a second gate structure positioned on the source bonding structure and including second insulating layers and second conductive layers alternately stacked; a second stack positioned on the first contact bonding structure and including the second insulating layers and second sacrificial layers alternately stacked; second channel structures extending into the source bonding structure through the second gate structure; and a second contact plug extending into the first contact bonding structure through the second stack.

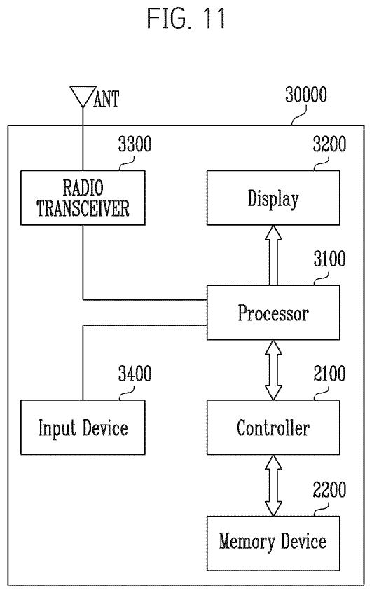

FIG. 11 is a simplified diagram illustrating a memory system according to an embodiment of the present disclosure.

Referring to FIG. 11, the memory system 30000 may be implemented as a cellular phone, a smart phone, a tablet, a personal computer (PC), a personal digital assistant (PDA), or a wireless communication device. The memory system 30000 may include a memory device 2200 and a controller 2100 capable of controlling an operation of the memory device 2200.

The controller 2100 may control a data access operation, for example, a program operation, an erase operation, a read operation, or the like, of the memory device 2200 under control of a processor 3100.

Data programmed in the memory device 2200 may be output through a display 3200 under the control of the controller 2100.

A radio transceiver 3300 may transmit and receive a radio signal through an antenna ANT. For example, the radio transceiver 3300 may convert the radio signal received through the antenna ANT into a signal that may be processed by the processor 3100. Therefore, the processor 3100 may process the signal output from the radio transceiver 3300 and transmit the processed signal to the controller 2100 or the display 3200. The controller 2100 may transmit the signal processed by the processor 3100 to the memory device 2200. In addition, the radio transceiver 3300 may convert a signal output from the processor 3100 into the radio signal, and output the converted radio signal to an external device through the antenna ANT. An input device 3400 may be a device capable of inputting a control signal for controlling an operation of the processor 3100 or data to be processed by the processor 3100, and may be implemented as a pointing device such as a touch pad or a computer mouse, a keypad, or a keyboard. The processor 3100 may control an operation of the display 3200 so that data output from the controller 2100, data output from the radio transceiver 3300, or data output from the input device 3400 is output through the display 3200.

According to an embodiment, the controller 2100 capable of controlling an operation of memory device 2200 may be implemented as a part of the processor 3100 and may be implemented as a chip separate from the processor 3100.

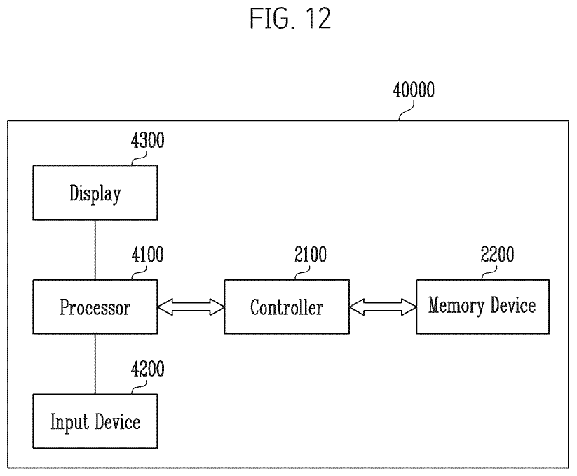

FIG. 12 is a simplified diagram illustrating a memory system according to an embodiment of the present disclosure.

Referring to FIG. 12, the memory system 40000 may be implemented as a personal computer (PC), a tablet, a notebook, an e-reader, a personal digital assistant (PDA), a portable multimedia player (PMP), an MP3 player, or an MP4 player.

The memory system 40000 may include the memory device 2200 and the controller 2100 capable of controlling a data process operation of the memory device 2200.

A processor 4100 may output data stored in the memory device 2200 through a display 4300, according to data input through an input device 4200. For example, the input device 4200 may be implemented as a pointing device such as a touch pad or a computer mouse, a keypad, or a keyboard.

The processor 4100 may control an overall operation of the memory system 40000 and control an operation of the controller 2100. According to an embodiment, the controller 2100 capable of controlling the operation of memory device 2200 may be implemented as a part of the processor 4100 or may be implemented as a chip separate from the processor 4100.

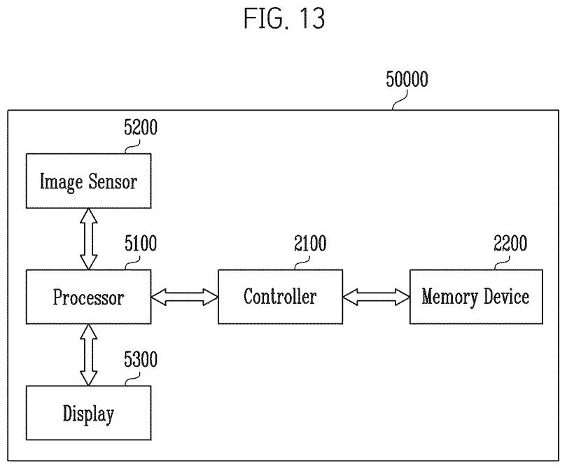

FIG. 13 is a simplified diagram illustrating a memory system according to an embodiment of the present disclosure.

Referring to FIG. 13, the memory system 50000 may be implemented as an image processing device, for example, a digital camera, a portable phone provided with a digital camera, a smart phone provided with a digital camera, or a tablet provided with a digital camera.

The memory system 50000 includes the memory device 2200 and the controller 2100 capable of controlling a data process operation, for example, a program operation, an erase operation, or a read operation, of the memory device 2200.

An image sensor 5200 of the memory system 50000 may convert an optical image into digital signals, and the converted digital signals may be transmitted to a processor 5100 or the controller 2100. Under control of the processor 5100, the converted digital signals may be output through a display 5300 or stored in the memory device 2200 through the controller 2100. In addition, data stored in the memory device 2200 may be output through the display 5300 under the control of the processor 5100 or the controller 2100.

According to an embodiment, the controller 2100 capable of controlling the operation of memory device 2200 may be implemented as a part of the processor 5100 or may be implemented as a chip separate from the processor 5100.

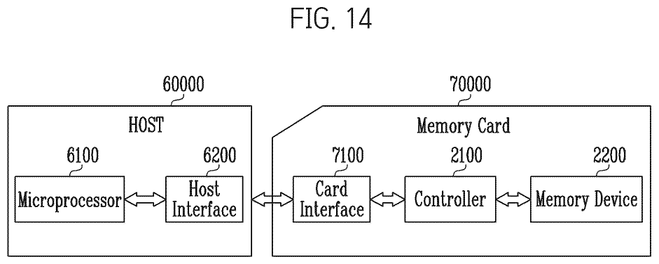

FIG. 14 is a simplified diagram illustrating a memory system according to an embodiment of the present disclosure.

Referring to FIG. 14, the memory system 70000 may be implemented as a memory card or a smart card. The memory system 70000 may include the memory device 2200, the controller 2100, and a card interface 7100.

The controller 2100 may control exchange of data between the memory device 2200 and the card interface 7100. According to an embodiment, the card interface 7100 may be a secure digital (SD) card interface or a multi-media card (MMC) interface, but the embodiments are not limited thereto.

The card interface 7100 may interface data exchange between a host 60000 and the controller 2100 according to a protocol of the host 60000. According to an embodiment, the card interface 7100 may support a universal serial bus (USB) protocol, and an interchip (IC)-USB protocol. Here, the card interface 7100 may refer to hardware capable of supporting a protocol that is used by the host 60000, software installed in the hardware, or a signal transmission method.

When the memory system 70000 is connected to a host interface 6200 of the host 60000 such as a PC, a tablet, a digital camera, a digital audio player, a mobile phone, a console video game hardware, or a digital set-top box, the host interface 6200 may perform data communication with the memory device 2200 through the card interface 7100 and the controller 2100 under control of a microprocessor 6100.

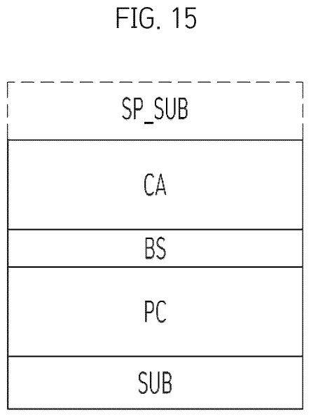

FIG. 15 is a simplified configuration diagram of a semiconductor device according to an embodiment of the present disclosure.

Referring to FIG. 15, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may include a semiconductor material. In an embodiment, the semiconductor material may include at least one of a group IV semiconductor, a group III-V compound semiconductor, and a group II-VI compound semiconductor. Here, the group IV semiconductor may include single crystalline silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductors may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well area doped with an n-type impurity and/or a p-well area doped with a p-type impurity.

The substrate SUB may be used as a support in a process of forming the peripheral circuit PC. Here, the peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transmitting an operation voltage and may include a contact plug, a line, and the like.

The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by a bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding interface, and the like. The bonding pad may include a metal and/or an alloy such as copper and aluminum. The bonding interface may include a non-metal-non-metal interface, a metal-metal interface, or the like. The memory cell array CA and the peripheral circuit PC may be electrically connected by the bonding structure BS.

For reference, the interconnection structure included in the cell array CA and/or the peripheral circuit PC may also be used as the bonding structure BS. In an embodiment, the interconnection structure included in the cell array CA and the interconnection structure included in the peripheral circuit PC may be directly bonded. In this case, a bit line, source line, or the like may be used as the bonding structure without a separate bonding pad.

The semiconductor device may also have a structure that combines the embodiments previously described with reference to FIG. 15 or have a partially modified structure. At least one memory cell array CA and/or at least one peripheral circuit PC may be additionally bonded to the embodiment described with reference to FIG. 15. For example, a third wafer including the memory cell array CA may be additionally manufactured, and then the third wafer may be bonded to the first wafer including the memory cell array CA. Here, the bonding structure BS may be for connecting the memory cell array CA and the memory cell array CA.

Although embodiments according to the technical spirit of the present disclosure have been described with reference to the accompanying drawings, this is only for describing an embodiment according to the concept of the present disclosure, and the present disclosure is not limited to the above-described embodiments. Within the scope of the technical spirit of the present disclosure described in the claims, various forms of substitution, modification, and change of the embodiments will be possible by those skilled in the art to which the present disclosure belongs, and these also belong to the scope of the present disclosure. Furthermore, the embodiments may be combined to form additional embodiments.

What is claimed is:

1. A semiconductor device comprising:
a peripheral circuit;
a first gate structure positioned over the peripheral circuit and including first insulating layers and first conductive layers alternately stacked;
a first stack positioned at a level corresponding to the first gate structure and including the first insulating layers and first sacrificial layers alternately stacked;
a source bonding structure positioned on the first gate structure;
a first contact bonding structure positioned on the first stack;
first channel structures extending partially into the source bonding structure through the first gate structure;
a first contact plug extending into the first contact bonding structure through the first stack;
a second gate structure positioned on the source bonding structure and including second insulating layers and second conductive layers alternately stacked;
a second stack positioned on the first contact bonding structure and including the second insulating layers and second sacrificial layers alternately stacked;
second channel structures extending into the source bonding structure through the second gate structure; and
a second contact plug extending into the first contact bonding structure through the second stack.

2. The semiconductor device of claim 1, wherein the first channel structures and the second channel structures share the source bonding structure.

3. The semiconductor device of claim 1, wherein the first contact plug and the second contact plug are electrically connected through the first contact bonding structure.

4. The semiconductor device of claim 1, wherein the source bonding structure and the first contact bonding structure are positioned at a corresponding level.

5. The semiconductor device of claim 1, wherein the source bonding structure includes a first source bonding pattern and a second source bonding pattern on the first source bonding pattern, and
the first source bonding pattern and the second source bonding pattern are directly bonded.

6. The semiconductor device of claim 1, wherein the first contact bonding structure includes a first contact bonding pattern and a second contact bonding pattern on the first contact bonding pattern, and
the first contact bonding pattern and the second contact bonding pattern are directly bonded.

7. The semiconductor device of claim 1, further comprising:
a dielectric bonding structure positioned at a level corresponding to the source bonding structure and the first contact bonding structure.

8. The semiconductor device of claim 1, wherein the first gate structure includes a first step structure exposing an upper surface of each of the first conductive layers, and the second gate structure includes a second step structure exposing an upper surface of each of the second conductive layers, and
the semiconductor device further comprises:
first contact vias extending through the first step structure and connected to the first conductive layers;
second contact vias extending through the second step structure and connected to the second conductive layers; and
a second contact bonding structure positioned on the first gate structure and positioned at a level corresponding to the source bonding structure.

9. The semiconductor device of claim 8, wherein the second contact vias are electrically connected to the peripheral circuit through the second contact bonding structure and the first contact vias.

10. The semiconductor device of claim 8, wherein the second contact bonding structure includes a third contact bonding pattern and a fourth contact bonding pattern on the third contact bonding pattern, and
the third contact bonding pattern and the fourth contact bonding pattern are directly bonded.

11. The semiconductor device of claim 8, wherein the second contact bonding structures are arranged in a first direction and a second direction crossing the first direction.

12. The semiconductor device of claim 1, wherein the first gate structure includes a first step structure exposing an upper surface of each of the first conductive layers, and the second gate structure includes a second step structure exposing an upper surface of each of the second conductive layers, and
the semiconductor device further comprises:
first contact vias directly connected to the upper surface of each of the first conductive layers and having different heights; and
second contact vias directly connected to the upper surface of each of the second conductive layers and have different heights.

13. The semiconductor device of claim 12, further comprising:
a third stack positioned at a level corresponding to the first stack;
a fourth stack positioned at a level corresponding to the second stack;
a third contact bonding structure positioned on the third stack and positioned at a level corresponding to the source bonding structure;
a third contact plug extending into the third contact bonding structure through the third stack; and
a fourth contact plug extending into the third contact bonding structure through the fourth stack.

14. The semiconductor device of claim 13, wherein the second contact vias are electrically connected to the peripheral circuit through the fourth contact plug, the third contact bonding structure, and the third contact plug.

15. The semiconductor device of claim 1, further comprising:
first contact vias extending through the first gate structure and connected to the first conductive layers; and
second contact vias extending through the second gate structure and connected to the second conductive layers.

16. The semiconductor device of claim 15, further comprising:
a third stack positioned at a level corresponding to the first stack;
a fourth stack positioned at a level corresponding to the second stack;
a third contact bonding structure positioned on the third stack and positioned at a level corresponding to the source bonding structure;
a third contact plug extending into the third contact bonding structure through the third stack; and
a fourth contact plug extending into the third contact bonding structure through the fourth stack.

17. The semiconductor device of claim 16, wherein the second contact vias are electrically connected to the peripheral circuit through the fourth contact plug, the third contact bonding structure, and the third contact plug.

18. The semiconductor device of claim 1, further comprising:
a dielectric bonding structure positioned between neighboring source bonding structures.

19. The semiconductor device of claim 18, wherein first contact bonding structures are positioned in the dielectric bonding structure.

20. The semiconductor device of claim 19, wherein the first contact bonding structures are insulated from each other by the dielectric bonding structure.

21. The semiconductor device of claim 1, wherein first contact bonding structures are arranged in a first direction and a second direction crossing the first direction.

22. The semiconductor device of claim 1, wherein the source bonding structure and the first contact bonding structure include the same or substantially the same material.

23. The semiconductor device of claim 22, wherein the source bonding structure and the first contact bonding structure include polysilicon.

24. A method of manufacturing a semiconductor device, the method comprising:
forming a first stack on a first substrate;
forming first channel structures extending into the first substrate through the first stack;
forming a first contact plug extending through the first stack;
removing the first substrate;
forming a first dielectric bonding layer on the first stack;
forming first openings exposing the first channel structures by partially removing the first dielectric bonding layer;
forming a second opening exposing the first contact plug by partially removing the first dielectric bonding layer;
forming first source bonding patterns in the first openings; and
forming a first contact bonding pattern in the second opening.

25. The method of claim 24, wherein when forming the first openings, the second opening is formed.

26. The method of claim 24, wherein when forming the first source bonding patterns, the first contact bonding pattern is formed.

27. The method of claim 24, wherein forming the first source bonding patterns comprises:
forming a conductive bonding layer on the first channel structures to fill the first openings;
annealing the conductive bonding layer; and
forming the first source bonding patterns in the first openings by planarizing the conductive bonding layer using the first dielectric bonding layer as a planarization barrier.

28. The method of claim 24, further comprising:
forming a first cell wafer including the first source bonding patterns, the first contact bonding pattern, the first dielectric bonding layer, the first contact plug, and the first channel structures;
forming a second cell wafer including a second stack, a second gate structure, second channel structures extending through the second gate structure, a second contact plug extending through the second stack, a second dielectric bonding layer formed on the second stack, second source bonding patterns formed on the second gate structure, and a second contact bonding pattern formed on the second stack; and
bonding the first cell wafer and the second cell wafer so that the first source bonding patterns and the second source bonding patterns are connected, the first contact bonding pattern and the second contact bonding pattern are connected, and the first dielectric bonding layer and the second dielectric bonding layer are connected.

29. The method of claim 28, wherein the second contact plug is electrically connected to the second contact bonding pattern, the first contact bonding pattern, and the first contact plug.

30. The method of claim 28, wherein the first stack includes first material layers and second material layers alternately stacked, the first stack includes a first step structure exposing an upper surface of each of the second material layers, and
the method further comprises forming first contact vias extending through the first step structure and respectively connected to the second material layers, before removing the first substrate.

31. The method of claim 30, wherein the second stack includes third material layers and fourth material layers alternately stacked, and the second stack includes a second step structure exposing an upper surface of each of the fourth material layers, and
wherein the second cell wafer further includes second contact vias extending through the second step structure and respectively connected to the fourth material layers.

32. The method of claim 31, wherein the first cell wafer further includes third contact bonding patterns formed at a level corresponding to the first source bonding patterns,
wherein the second cell wafer further includes fourth contact bonding patterns formed at a level corresponding to the second source bonding patterns, and
wherein the second contact vias are electrically connected to the fourth contact bonding patterns, the fourth contact bonding patterns, and the first contact vias.

33. The method of claim 28, wherein the first stack includes first material layers and second material layers alternately stacked, the first stack includes a first step structure exposing an upper surface of each of the second material layers, and
the method further comprises forming first contact vias directly connected to an upper surface of each of the second material layers and having different heights, before removing the first substrate.

34. The method of claim 33, wherein the second stack includes third material layers and fourth material layers alternately stacked, the second stack includes a second step structure exposing an upper surface of each of the fourth material layers, and
wherein the second cell wafer further includes second contact vias directly connected to the upper surface of each of the fourth material layers and having different heights.

35. The method of claim 34, wherein the first cell wafer further includes a third stack formed at a level corresponding to the first stack, a fifth contact bonding pattern formed at a level corresponding to the first source bonding patterns, and a third contact plug extending into the fifth contact bonding pattern through the third stack,
wherein the second cell wafer further includes a fourth stack formed at a level corresponding to the second stack, a sixth contact bonding pattern formed at a level corresponding to the second source bonding patterns, and a fourth contact plug extending into the sixth contact bonding pattern through the fourth stack, and
wherein the second contact vias are electrically connected to the fourth contact plug, the sixth contact bonding pattern, and the fifth contact bonding pattern.

36. The method of claim 28, wherein the first stack includes first material layers and second material layers alternately stacked, and
the method further comprises forming first contact vias extending through the first stack and connected to the second material layers.

37. The method of claim 36, wherein the second stack includes third material layers and fourth material layers alternately stacked, and
wherein the second cell wafer further includes second contact vias extending through the second stack and connected to the fourth material layers.

38. The method of claim 37, wherein the first cell wafer further includes a third stack formed at a level corresponding to the first stack, a fifth contact bonding pattern formed at a level corresponding to the first source bonding patterns, and a third contact plug extending into the fifth contact bonding pattern through the third stack,
wherein the second cell wafer further includes a fourth stack formed at a level corresponding to the second stack, a sixth contact bonding pattern formed at a level corresponding to the second source bonding patterns, and a fourth contact plug extending into the sixth contact bonding pattern through the fourth stack, and
wherein the second contact vias are electrically connected to the fourth contact plug, the sixth contact bonding pattern, and the fifth contact bonding pattern.
